(19) United States
(12) Patent Application Publication
(10) Pub. No.: US 2025/0359265 A1
(43) Pub. Date: Nov. 20, 2025

(54) SEMICONDUCTOR DEVICE AND METHODS OF FABRICATION THEREOF

(71) Applicant: TAIWAN SEMICONDUCTOR MANUFACTURING COMPANY, LTD., Hsinchu (TW)

(72) Inventors: Chung-Ting KO, Kaohsiung (TW); Shu Ling LIAO, Taichung (TW); Sung-En LIN, Hsinchu (TW)

(21) Appl. No.: 19/291,711

(22) Filed: Aug. 6, 2025

Related U.S. Application Data
(63) Continuation of application No. 18/527,714, filed on Dec. 4, 2023.
(60) Provisional application No. 63/530,905, filed on Aug. 4, 2023.

(51) Int. Cl. H10D 64/23; H10D 30/01; H10D 30/43; H10D 30/67; H10D 62/10; H10D 64/01

(52) U.S. Cl. CPC H10D 64/258; H10D 30/014; H10D 30/43; H10D 30/6735; H10D 30/6757; H10D 62/121; H10D 64/017

(57) ABSTRACT

A semiconductor device structure is provided. The semiconductor device structure includes a source/drain (S/D) feature disposed over a substrate between two adjacent semiconductor layers, a supporting layer disposed between the S/D feature and the substrate, the supporting layer having a curved top surface, a dielectric spacer disposed between and in contact with one of the semiconductor layers and the substrate, wherein the dielectric spacer, the substrate, the supporting layer, and a bottom surface of the S/D feature define an air gap therein.

### CROSS-REFERENCE TO RELATED APPLICATIONS

This application is a continuation application of U.S. patent application Ser. No. 18/527,714 filed Dec. 4, 2023, which claims priority to U.S. Provisional Application Ser. No. 63/530,905 filed Aug. 4, 2023, which is incorporated by reference in their entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down presents new challenge. For example, it becomes an increasing challenge to reduce parasitic capacitance between source/drain features and gate while maintaining desired K value for the devices. Improved structures and methods for manufacturing the same are needed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-8 are perspective views of various stages of manufacturing a semiconductor device structure, in accordance with some embodiments.

FIGS. 9A-10A and 22A-27A are cross-sectional side views of various stages of manufacturing the semiconductor device structure taken along cross-section A-A of FIG. 8, in accordance with some embodiments.

FIGS. 9B-10B and 22B-27B are cross-sectional side views of various stages of manufacturing the semiconductor device structure taken along cross-section B-B of FIG. 8, in accordance with some embodiments.

FIGS. 9C-10C and 22C-27C are cross-sectional side views of various stages of manufacturing the semiconductor device structure taken along cross-section C-C of FIG. 8, in accordance with some embodiments.

FIGS. 11 to 19 are cross-sectional side views of various stages of manufacturing the semiconductor device structure taken along cross-section A-A of FIG. 8, in accordance with some embodiments.

FIG. 14-1 is an enlarged view of a portion of the semiconductor device structure, in accordance with some embodiments.

FIGS. 20-1A and 20-1B are cross-sectional side views of the semiconductor device structure, in accordance with some embodiments.

FIGS. 21-1A to 21-1D illustrate cross-sectional side views of various stages of manufacturing the semiconductor device structure, in accordance with some alternative embodiments.

FIG. 21-2 illustrates an enlarged view of a portion of the semiconductor device structure in FIG. 21-1D, in accordance with some alternative embodiments.

FIG. 22A-1 illustrates an enlarged view of a portion of the semiconductor device structure shown in FIG. 22A.

FIGS. 22D-27D are cross-sectional side views of various stages of manufacturing the semiconductor device structure taken along cross-section D-D of FIG. 22A, in accordance with some embodiments.

FIGS. 28-31 illustrate an enlarged view of a portion of the semiconductor device structure, in accordance with some embodiments.

FIGS. 32A and 32B are a flowchart of a method for fabricating the semiconductor device, according to embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is generally related to semiconductor devices, and more particularly to field-effect transistors (FETs), such as planar FETs, three-dimensional fin-line FETs (FinFETs), gate-all-around (GAA) devices (e.g., Horizontal Gate All Around (HGAA) FETs, Vertical Gate All Around (VGAA) FETs), vertical FETs, forksheet FETs, or complementary FETs (CFETs). While the embodiments of this disclosure are discussed with respect to GAA devices, implementations of some aspects of the present disclosure may be used in other processes and/or in other devices. A person having ordinary skill in the art will readily understand other modifications that may be made are contemplated within the scope of this disclosure.

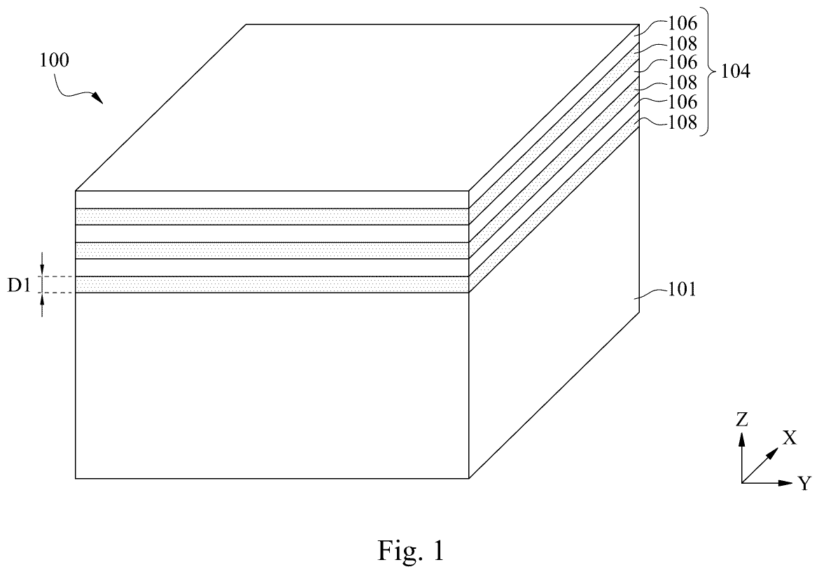

FIGS. 1-32B show exemplary processes for manufacturing a semiconductor device structure 100 according to embodiments of the present disclosure. It is understood that additional operations can be provided before, during, and after processes shown by FIGS. 1-32B, and some of the operations described below can be replaced or eliminated, for additional embodiments of the method. The order of the operations/processes is not limiting and may be interchangeable.

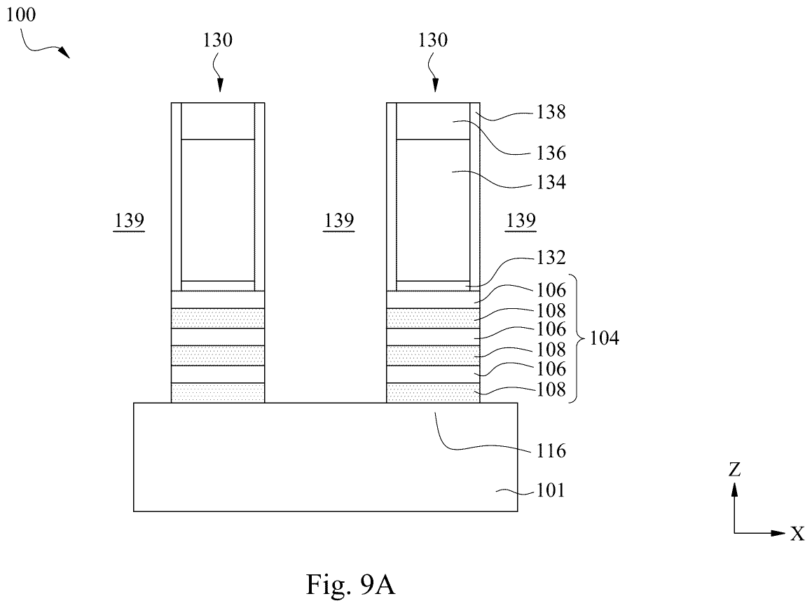

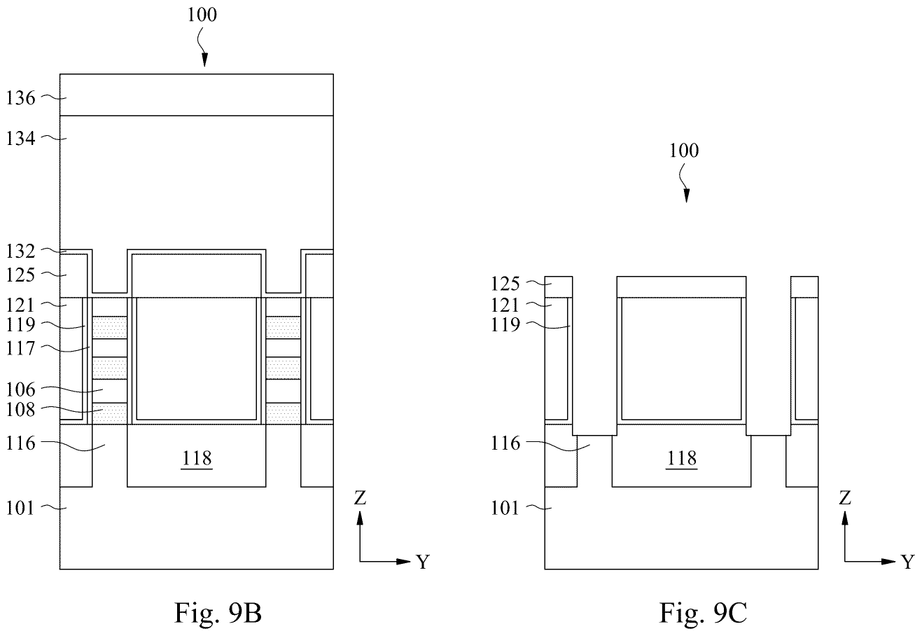

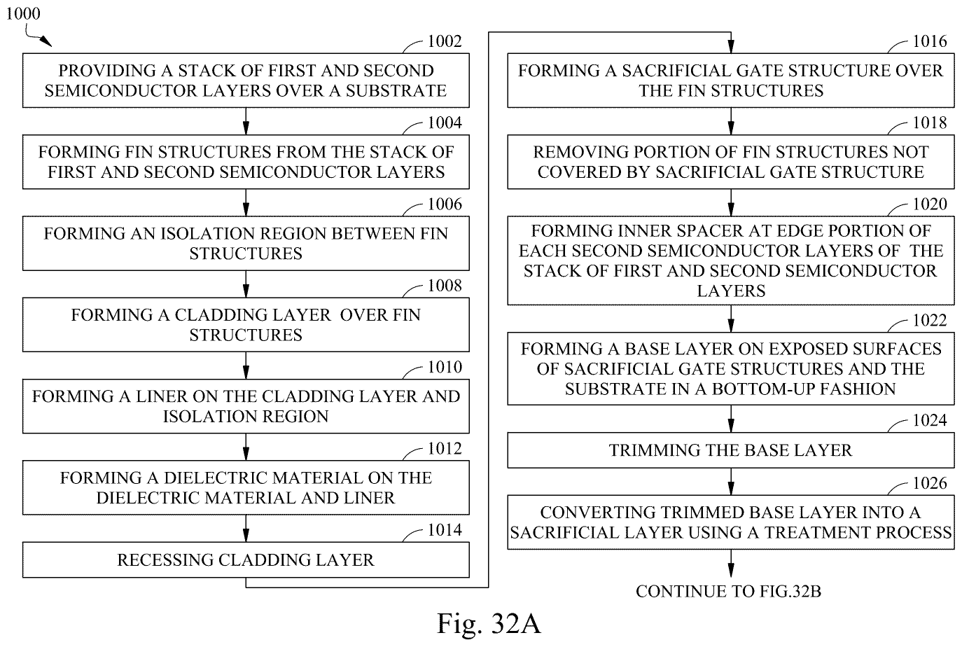

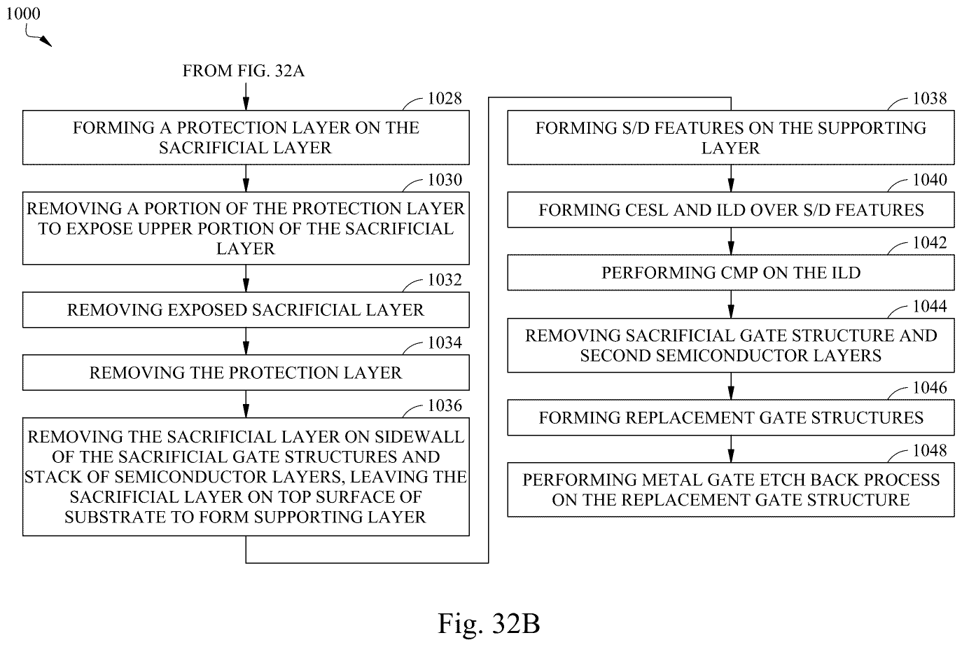

FIGS. 1-8 are perspective views of various stages of manufacturing a semiconductor device structure 100 in accordance with some embodiments. FIGS. 32A and 32B are a flowchart of a method 1000 for fabricating the semiconductor device 100 according to embodiments of the present disclosure. FIGS. 9A-31 schematically illustrate the semiconductor device 100 at various stages of fabrication according to the method 1000. It is understood that additional steps can be provided before, during, and/or after the method 1000, and some of the steps described can be replaced, eliminated, and/or moved around for additional embodiments of the method 1000.

At block 1002, the semiconductor device structure 100 including a stack of semiconductor layers 104 formed over a substrate 101 is provided, as shown in FIG. 1. The substrate 101 may be a semiconductor substrate. The substrate 101 may include a crystalline semiconductor material such as, but not limited to, silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In one embodiment, the substrate 101 is made of silicon. In some embodiments, the substrate 101 is a silicon-on-insulator (SOI) substrate having an insulating layer (not shown) disposed between two silicon layers for enhancement. In one aspect, the insulating layer is an oxygen-containing layer.

The substrate 101 may include various regions that have been doped with impurities (e.g., dopants having p-type or n-type impurities). Depending on circuit design, the dopants may be, for example boron for p-type field effect transistors (p-type FETs) and phosphorus for n-type field effect transistors (n-type FETs).

The stack of semiconductor layers 104 includes semiconductor layers made of different materials to facilitate formation of nanosheet channels in a multi-gate device, such as nanosheet FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108, and the first and second semiconductor layers 106, 108 are disposed parallelly with each other. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. In some embodiments, the first semiconductor layers 106 may be made of SiGe having a first Ge concentration range, and the second semiconductor layers 108 may be made of SiGe having a second Ge concentration range that is lower or greater than the first Ge concentration range. In any case, the second semiconductor layers 108 may have a Ge concentration in a range between about 20 at. % (atomic percentage) and 30 at. %.

The thickness of the first semiconductor layers 106 and the second semiconductor layers 108 may vary depending on the application and/or device performance considerations. In some embodiments, each first and second semiconductor layer 106, 108 may have a thickness in a range between about 5 nm and about 30 nm. Each second semiconductor layer 108 may have a thickness that is equal to, less than, or greater than the thickness of the first semiconductor layer 106. In some embodiments, each first semiconductor layer 106 has a thickness in a range between about 10 nm and about 30 nm, and each second semiconductor layer 108 has a thickness in a range between about 5 nm to about 20 nm. The second semiconductor layers 108 may eventually be removed and serve to define a vertical distance between adjacent channels for the semiconductor device structure 100.

The first semiconductor layers 106 or portions thereof may form nanosheet channel(s) of the semiconductor device structure 100 in later fabrication stages. The term nanosheet is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanosheet channel(s) of the semiconductor device structure 100 may be surrounded by a gate electrode. The semiconductor device structure 100 may include a nanosheet transistor. The nanosheet transistors may be referred to as nanosheet transistors, nanowire transistors, gate-all-around (GAA) transistors, multi-bridge channel (MBC) transistors, or any transistors having the gate electrode surrounding the channels. The use of the first semiconductor layers 106 to define channels of the semiconductor device structure 100 is further discussed below.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes. While three first semiconductor layers 106 and three second semiconductor layers 108 are alternately arranged as illustrated in FIG. 1, it can be appreciated that any number of first and second semiconductor layers 106, 108 can be formed in the stack of semiconductor layers 104, depending on the predetermined number of nanosheet channels for each FET. For example, the number of first semiconductor layers 106, which is the number of channels, may be between 2 and 8.

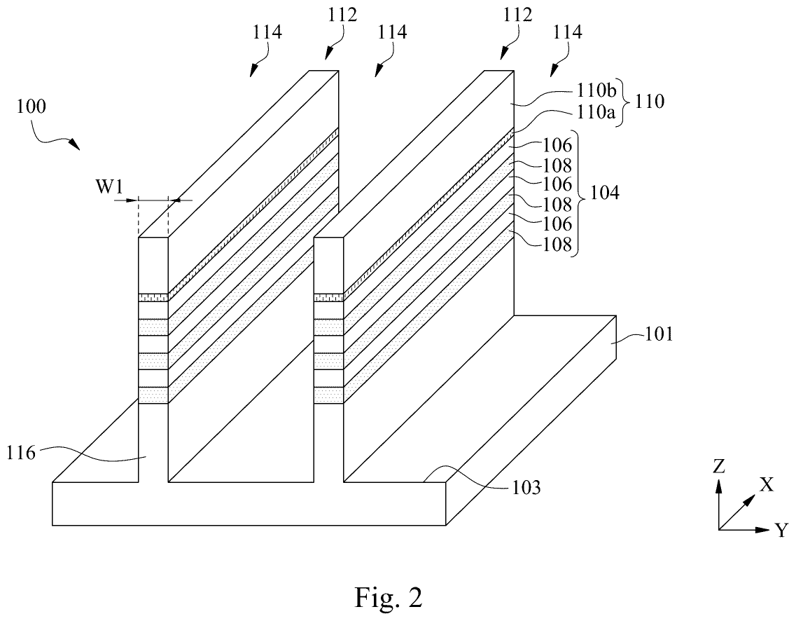

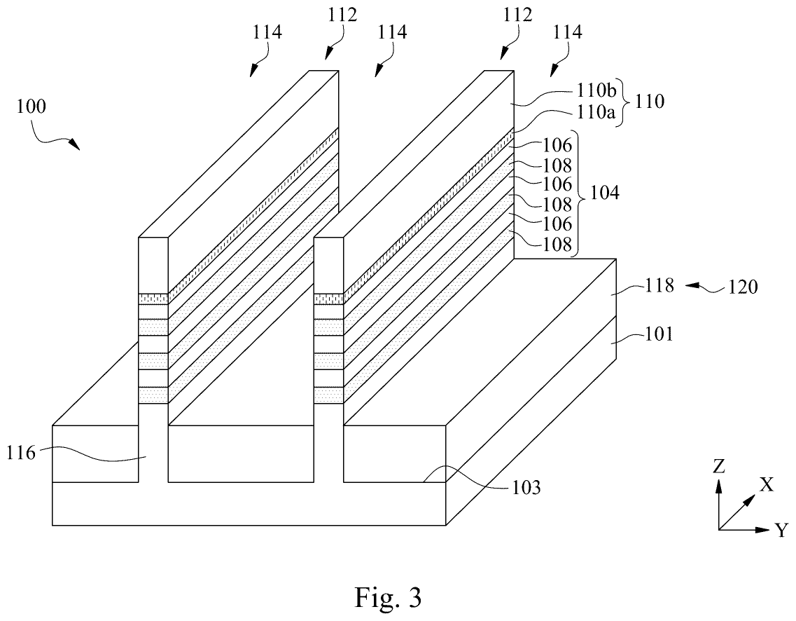

At block 1004, fin structures 112 are formed from the stack of semiconductor layers 104, as shown in FIG. 2. Each fin structure 112 has an upper portion including the semiconductor layers 106, 108 and a well portion 116 formed from the substrate 101. A mask structure 110 is formed over the stack of semiconductor layers 104 prior to forming the fin structures 112. The mask structure 110 may include a pad layer 110a and a hard mask 110b. The pad layer 110a may be an oxygen-containing layer, such as a SiO₂ layer. The hard mask 110b may be a nitrogen-containing layer, such as a Si₃N₄ layer. The mask structure 110 may be formed by any suitable deposition process, such as chemical vapor deposition (CVD) process.

The fin structures 112 may be formed by patterning the mask structure 110 using one or more photolithography processes and etching processes. The etching process can include dry etching, wet etching, reactive ion etching (RIE), and/or other suitable processes. The photolithography process may include double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. As an example of one multi-patterning process, a sacrificial layer may be formed over a substrate and patterned using a photolithography process. Spacers are formed alongside the patterned sacrificial layer using a self-aligned process. The sacrificial layer is then removed, and the remaining spacers may then be used to pattern the fin structures 112. In any case, the one or more etching processes form trenches 114 in unprotected regions through the mask structure 110, through the stack of semiconductor layers 104, and into the substrate 101, thereby leaving the plurality of extending fin structures 112. A width W1 of the fin structures 112 along the Y direction may be in a range between about 1.5 nm and about 44 nm, for example about 2 nm to about 6 nm. The trenches 114 may be etched using a dry etch (e.g., RIE), a wet etch, and/or combination thereof. While two fin structures 112 are shown, the number of the fin structures is not limited to two.

FIG. 2 further illustrates the fin structures 112 having substantially vertical sidewalls, such that width of the fin structures 112 are substantially similar and each of the first and second semiconductor layers 106, 108 in the fin structures 112 is rectangular in shape. In some embodiments, the fin structures 112 may have tapered sidewalls, such that a width of each of the fin structures 112 continuously increases in a direction towards the substrate 101. In such cases, each of the first and second semiconductor layers 106, 108 in the fin structures 112 may have a different width and be trapezoidal in shape.

At block 1006, after the fin structures 112 are formed, an insulating material 118 is formed in the trenches 114 between the fin structures 112, as shown in FIG. 3. The insulating material 118 fills the trenches 114 between neighboring fin structures 112 until the fin structures 112 are embedded in the insulating material 118. Then, a planarization operation, such as a chemical mechanical polishing (CMP) process and/or an etch-back process, is performed to expose the top of the fin structures 112. The insulating material 118 may be made of silicon oxide, silicon nitride, silicon oxynitride (SiON), SiOCN, SiCN, fluorine-doped silicate glass (FSG), a low-k dielectric material, or any suitable dielectric material. The insulating material 118 may be formed by any suitable method, such as low-pressure chemical vapor deposition (LPCVD), plasma enhanced CVD (PECVD) or flowable CVD (FCVD).

Thereafter, the insulating material 118 is recessed to form an isolation region 120. After recessing, portions of the fin structures 112, such as the stack of semiconductor layers 104, may protrude from between neighboring isolation regions 120. The isolation regions 120 may have top surfaces that are flat as illustrated, convex, concave, or a combination thereof. The recess of the insulating material 118 reveals the trenches 114 between the neighboring fin structures 112. The insulating material 118 may be recessed using a suitable process, such as a dry etching process, a wet etching process, or a combination thereof. Upon completion of recessing, a top surface of the insulating material 118 may be level with or below a surface of the second semiconductor layers 108 in contact with the well portion 116 formed from the substrate 101.

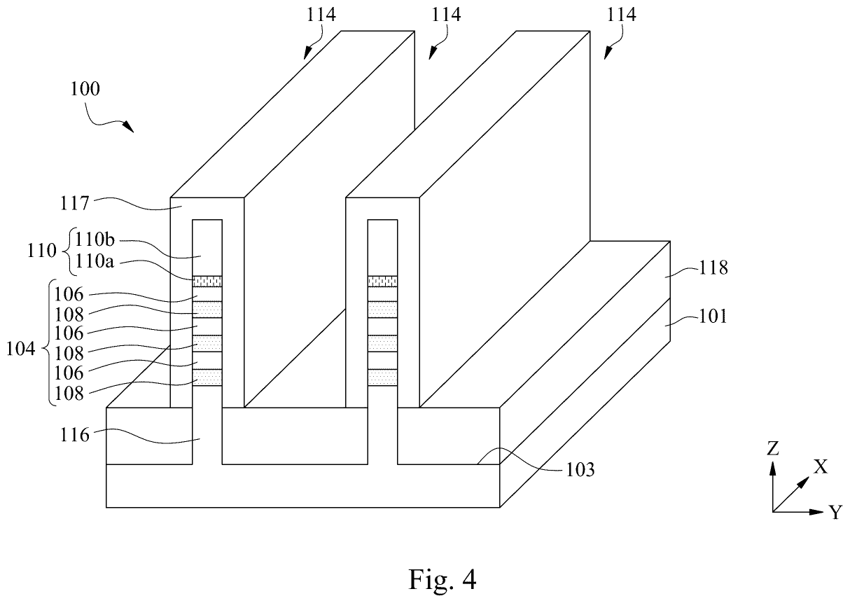

At block 1008, a cladding layer 117 is formed by an epitaxial process over exposed portion of the fin structures 112, as shown in FIG. 4. In some embodiments, a semiconductor liner (not shown) may be first formed over the fin structures 112, and the cladding layer 117 is then formed over the semiconductor liner. The semiconductor liner may be diffused into the cladding layer 117 during the formation of the cladding layer 117. In either case, the cladding layer 117 is in contact with the stack of semiconductor layers 104. In some embodiments, the cladding layer 117 and the second semiconductor layers 108 include the same material having the same etch selectivity. For example, the cladding layer 117 and the second semiconductor layers 108 may be or include SiGe. The cladding layer 117 and the second semiconductor layers 108 may be removed subsequently to create space for the subsequently formed gate electrode layer.

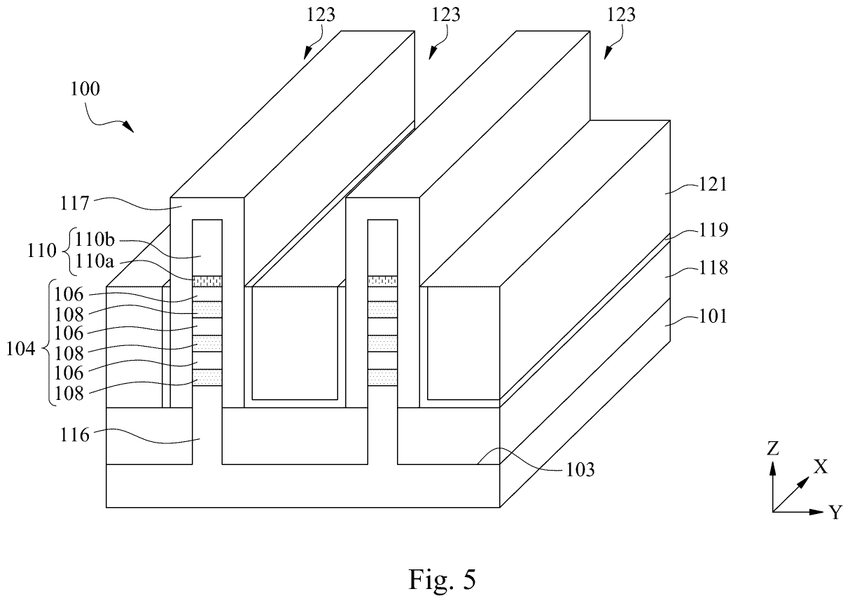

At block 1010, a liner 119 is formed on the cladding layer 117 and the top surface of the insulating material 118, as shown in FIG. 5. The liner 119 may include a material having a k value lower than 7, such as SiO₂, SiN, SiCN, SiOC, or SiOCN. The liner 119 may be formed by a conformal process, such as an ALD process. A dielectric material 121 is then formed in the trenches 114 (FIG. 4) and on the liner 119. The dielectric material 121 may be an oxygen-containing material, such as an oxide, formed by FCVD. The oxygen-containing material may have a k value less than about 7, for example less than about 3. A planarization process, such as a CMP process, may be performed to remove portions of the liner 119 and the dielectric material 121 formed over the fin structures 112. The portion of the cladding layer 117 disposed on the hard mask 110b is exposed after the planarization process.

Next, the liner 119 and the dielectric material 121 are recessed to the level of the topmost first semiconductor layer 106. For example, in some embodiments, after the recess process, the top surfaces of the liner 119 and the dielectric material 121 may be level with a top surface of the uppermost first semiconductor layer 106. The recess processes may be selective etch processes that do not substantially affect the semiconductor material of the cladding layer 117. As a result of the recess process, trenches 123 are formed between the fin structures 112.

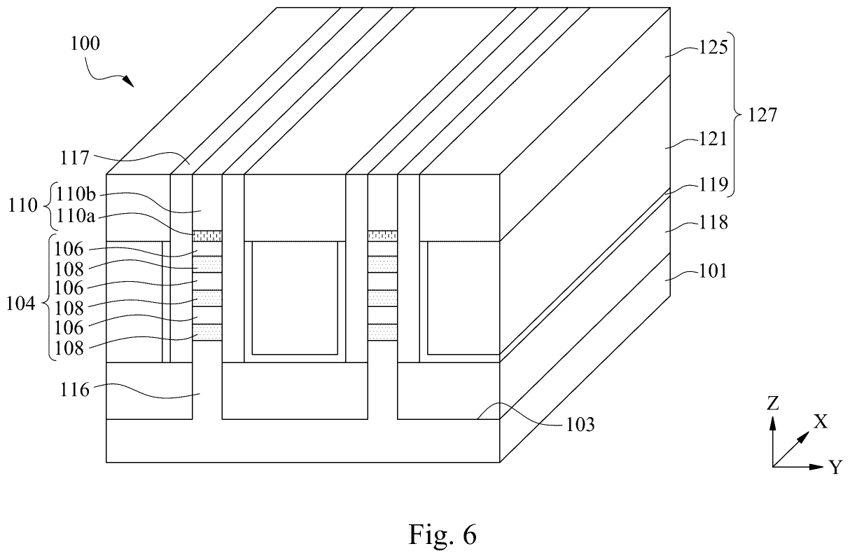

At block 1012, a dielectric material 125 is formed in the trenches 123 (FIG. 5) and on the dielectric material 121 and the liner 119, as shown in FIG. 6. The dielectric material 125 may include SiO, SiN, SiC, SiCN, SION, SiOCN, AIO, AlN, AlON, ZrO, ZrN, ZrAlO, HfO, or other suitable dielectric material. In some embodiments, the dielectric material 125 includes a high-k dielectric material (e.g., a material having a k value greater than 7). The dielectric material 125 may be formed by any suitable process, such as a CVD, PECVD, FCVD, or ALD process. A planarization process, such as a CMP process, is performed until the hard mask 110b of the mask structure 110 is exposed. The planarization process removes portions of the dielectric material 125 and the cladding layer 117 disposed over the mask structure 110. The liner 119, the dielectric material 121, and the dielectric material 125 together may be referred to as a dielectric feature 127 or a hybrid fin. The dielectric feature 127 serves to separate subsequent formed source/drain (S/D) epitaxial features and adjacent gate electrode layers.

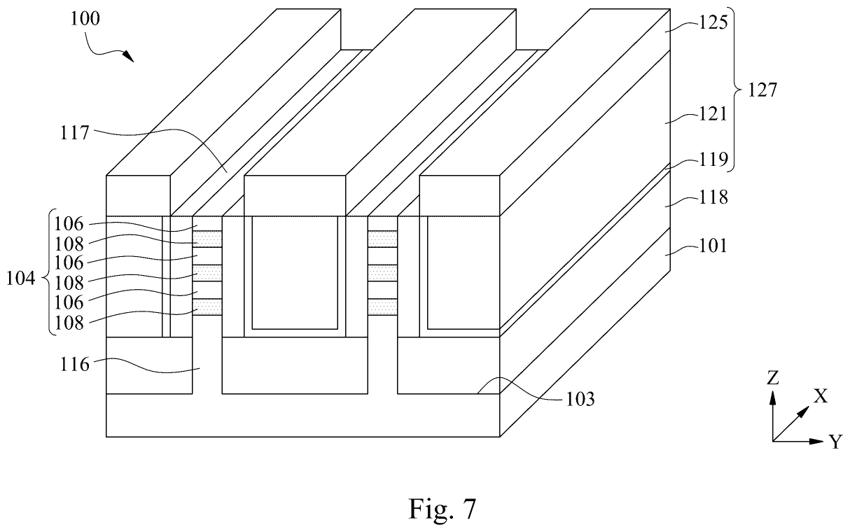

At block 1014, the cladding layers 117 are recessed, and the mask structures 110 are removed, as shown in FIG. 7. The recess of the cladding layers 117 may be performed by any suitable process, such as dry etch, wet etch, or a combination thereof. The recess process may be controlled so that the remaining cladding layers 117 are substantially at the same level as the top surface of the uppermost first semiconductor layer 106 in the stack of semiconductor layers 104. The etch process may be a selective etch process that does not substantially affect the dielectric material 125. The removal of the mask structures 110 may be performed by any suitable process, such as dry etch, wet etch, or a combination thereof.

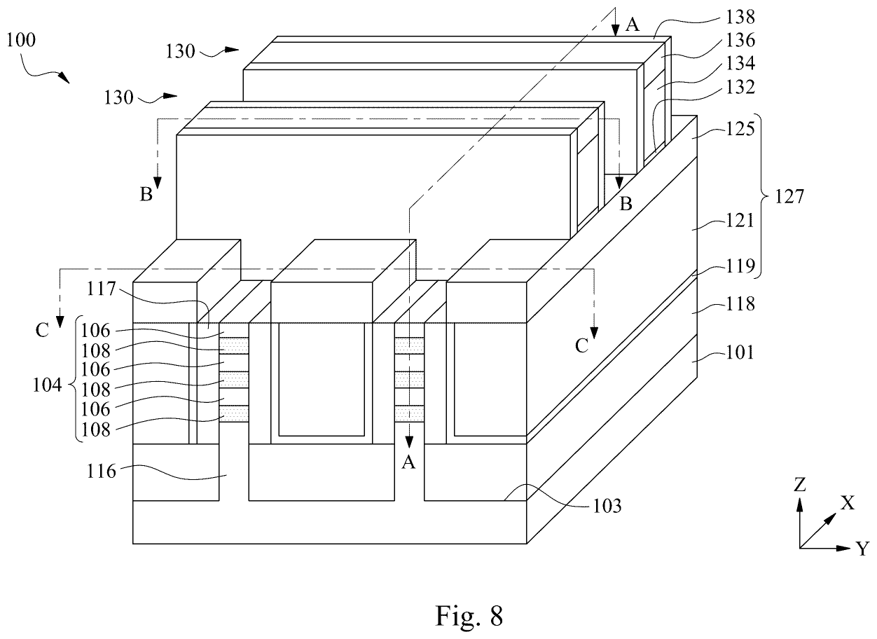

At block 1016, one or more sacrificial gate structures 130 (only two is shown) are formed over the semiconductor device structure 100, as shown in FIG. 8. The sacrificial gate structures 130 are formed over a portion of the fin structures 112. Each sacrificial gate structure 130 may include a sacrificial gate dielectric layer 132, a sacrificial gate electrode layer 134, and a mask layer 136. The sacrificial gate dielectric layer 132, the sacrificial gate electrode layer 134, and the mask layer 136 may be formed by sequentially depositing blanket layers of the sacrificial gate dielectric layer 132, the sacrificial gate electrode layer 134, and the mask layer 136, followed by pattern and etch processes. For example, the pattern process includes a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etch (e.g., RIE), wet etch, other etch methods, and/or combinations thereof.

By patterning the sacrificial gate structure 130, the stacks of semiconductor layers 104 of the fin structures 112 are partially exposed on opposite sides of the sacrificial gate structure 130. The portions of the fin structures 112 that are covered by the sacrificial gate electrode layer 134 of the sacrificial gate structure 130 serve as channel regions for the semiconductor device structure 100. The fin structures 112 that are partially exposed on opposite sides of the sacrificial gate structure 130 define source/drain (S/D) regions for the semiconductor device structure 100. In some cases, some S/D regions may be shared between various transistors. For example, various one of the S/D regions may be connected together and implemented as multiple functional transistors. While two sacrificial gate structures 130 are shown, more or less sacrificial gate structures 130 may be arranged along the X direction in some embodiments.

Next, gate spacers 138 are formed on sidewalls of the sacrificial gate structures 130. The gate spacers 138 may be formed by first depositing a conformal layer that is subsequently etched back to form sidewall gate spacers 138. For example, a spacer material layer can be disposed conformally on the exposed surfaces of the semiconductor device structure 100. The conformal spacer material layer may be formed by an ALD process. Subsequently, anisotropic etch is performed on the spacer material layer using, for example, RIE. During the anisotropic etch process, most of the spacer material layer is removed from horizontal surfaces, such as the tops of the fin structures 112, the cladding layer 117, the dielectric material 125, leaving the gate spacers 138 on the vertical surfaces, such as the sidewalls of sacrificial gate structures 130. The gate spacer 138 may be made of a dielectric material such as silicon oxide, silicon nitride, silicon carbide, silicon oxynitride, SiCN, silicon oxycarbide, SiOCN, and/or combinations thereof.

In some embodiments where the cladding layers 117 and the dielectric features 127 are not present, portions of the sacrificial gate structures 130 and the gate spacers 138 are formed on the insulating material 118, and gaps are formed between exposed portions of the fin structures 112.

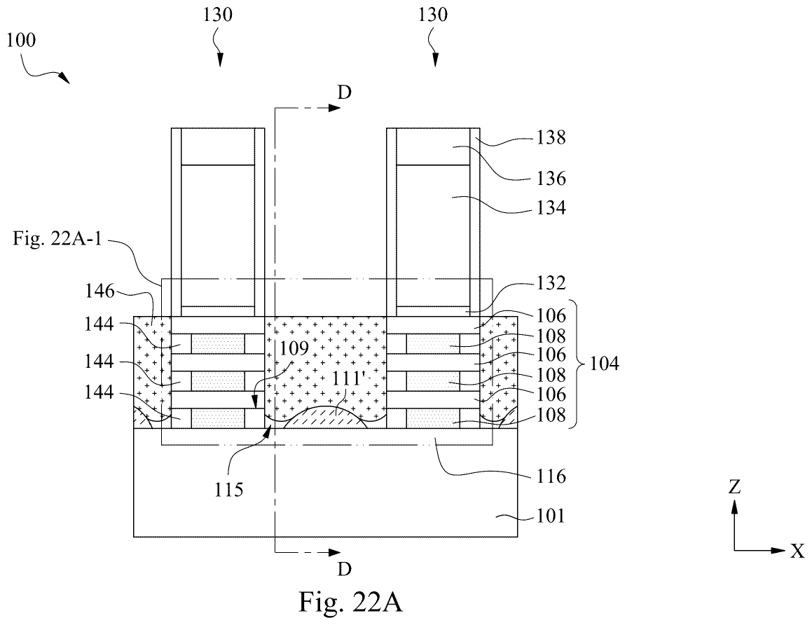

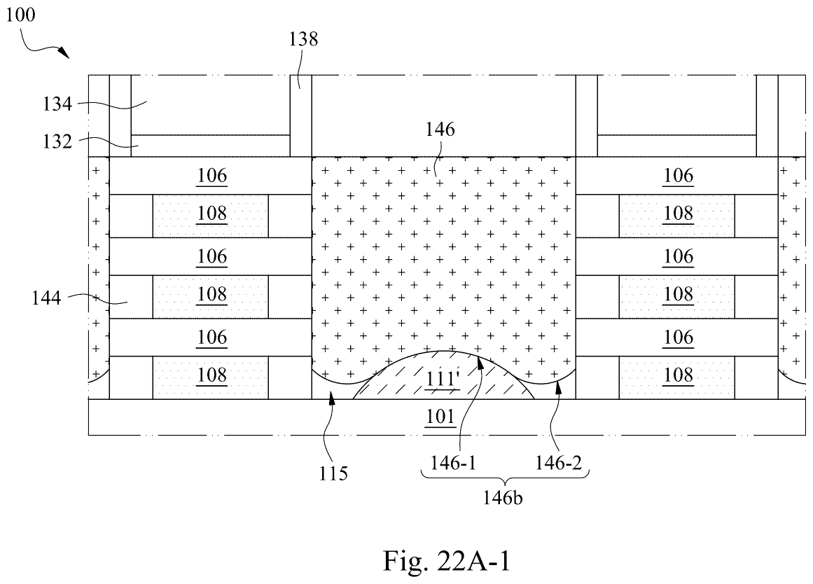

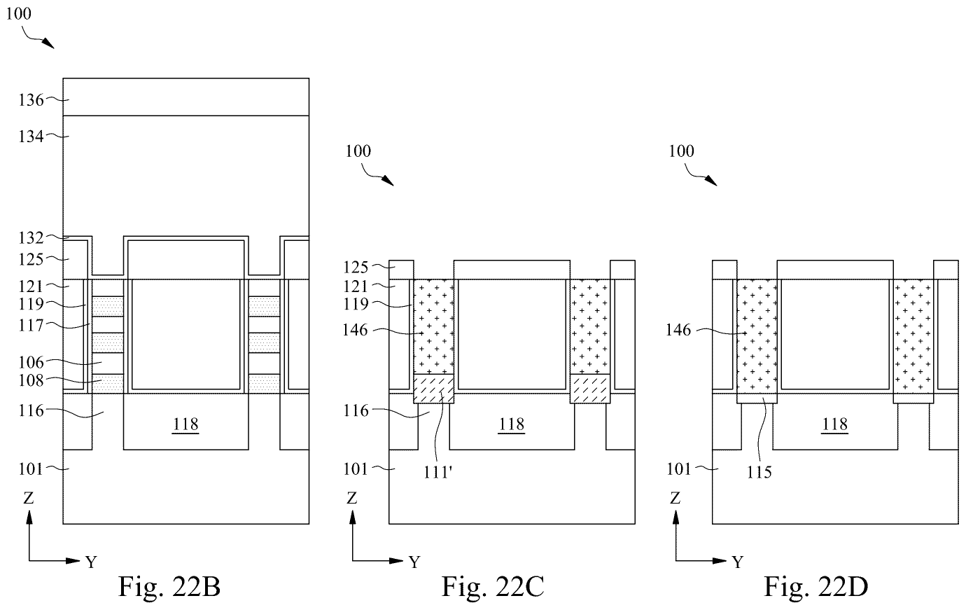

FIGS. 9A-10A and 22A-27A are cross-sectional side views of various stages of manufacturing the semiconductor device structure 100 taken along cross-section A-A of FIG. 8, in accordance with some embodiments. FIGS. 9B-10B and 22B-27B are cross-sectional side views of various stages of manufacturing the semiconductor device structure 100 taken along cross-section B-B of FIG. 8, in accordance with some embodiments. FIGS. 9C-10C and 22C-27C are cross-sectional side views of various stages of manufacturing the semiconductor device structure 100 taken along cross-section C-C of FIG. 8, in accordance with some embodiments. FIGS. 11 to 19 are cross-sectional side views of various stages of manufacturing the semiconductor device structure 100 taken along cross-section A-A of FIG. 8, in accordance with some embodiments. Cross-section A-A is in a plane of the fin structure 112 along the X direction. Cross-section B-B is in a plane perpendicular to cross-section A-A and is in the sacrificial gate structure 130. Cross-section C-C is in a plane perpendicular to cross-section A-A and is in the S/D epitaxial features 146 (FIG. 22A) along the Y-direction. FIGS. 22D-27D are cross-sectional side views of various stages of manufacturing the semiconductor device structure 100 taken along cross-section D-D of FIG. 22A, in accordance with some embodiments.

At block 1018, exposed portions of the stacks of semiconductor layers 104 of the fin structures 112, exposed portions of the cladding layers 117, and a portion of the exposed dielectric material 125 not covered by the sacrificial gate structures 130 and the gate spacers 138 are removed to form recess 139 for the S/D features, as shown in FIGS. 9A and 9C. The removal of the layers may be done by using one or more suitable etch processes, such as dry etch, wet etch, or a combination thereof. The one or more etch processes may be performed until the well portions 116 are exposed. The exposed portions of the fin structures 112 may be recessed to a level at the bottom surface of the second semiconductor layer 108 in contact with the well portion 116 of the substrate 101.

At block 1020, edge portions of each second semiconductor layer 108 of the stack of semiconductor layers 104 are removed horizontally along the X direction. The removal of the edge portions of the second semiconductor layers 108 forms cavities. In some embodiments, the portions of the second semiconductor layers 108 are removed by a selective wet etching process. In cases where the second semiconductor layers 108 are made of SiGe and the first semiconductor layers 106 are made of silicon and/or SiGe having lower germanium concentration than the second semiconductor layers 108, the second semiconductor layer 108 can be selectively etched using a wet etchant such as, but not limited to, ammonium hydroxide (NH₄OH), tetramethylammonium hydroxide (TMAH), ethylenediamine pyrocatechol (EDP), or potassium hydroxide (KOH) solutions.

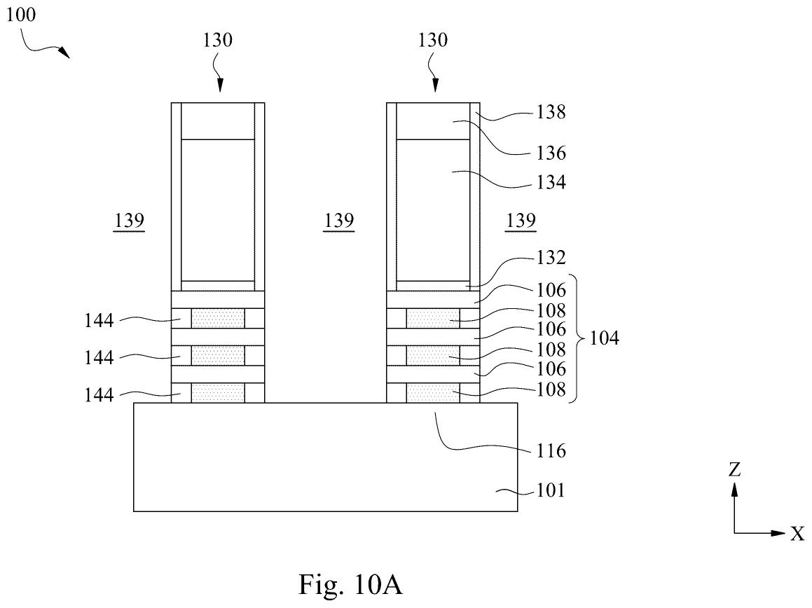

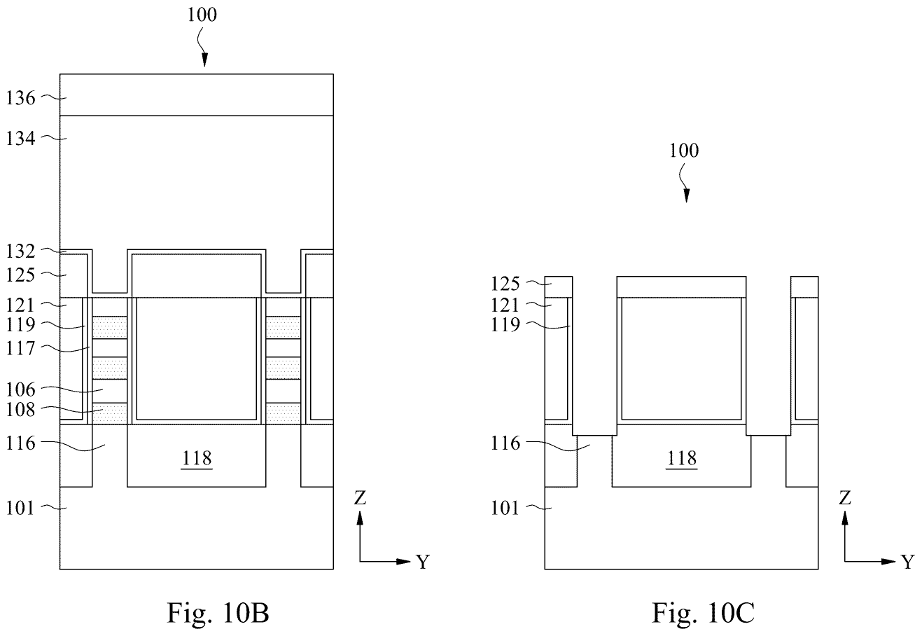

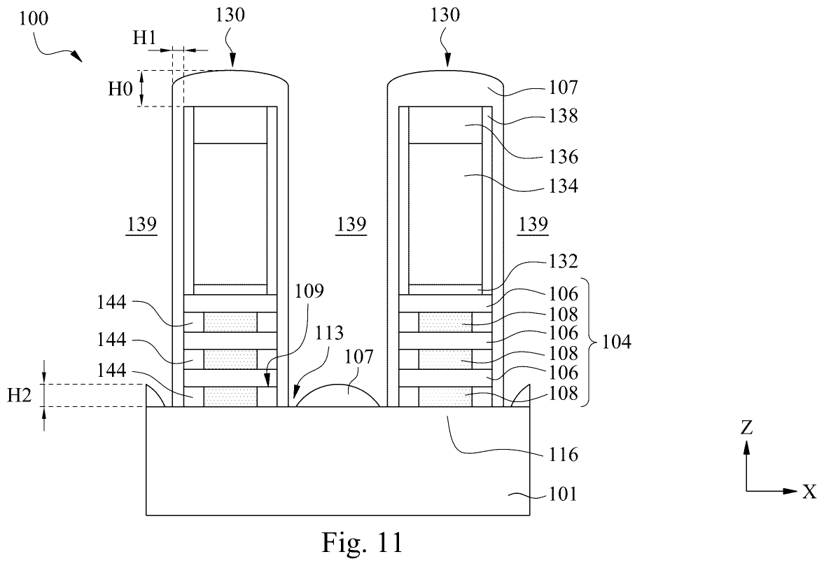

After removing edge portions of each second semiconductor layers 108, a dielectric layer is deposited in the cavities to form dielectric spacers (or so-called inner spacer) 144, as shown in FIG. 10A. The dielectric spacers 144 may be made of SiON, SiCN, SiOC, SiOCN, or SiN. The dielectric spacers 144 may be formed by first forming a conformal dielectric layer using a conformal deposition process, such as ALD, followed by an anisotropic etching to remove portions of the conformal dielectric layer other than the dielectric spacers 144. The dielectric spacers 144 are protected by the first semiconductor layers 106 during the anisotropic etching process. The remaining second semiconductor layers 108 are capped between the dielectric spacers 144 along the X direction.

At block 1022, a base layer 107 is formed on exposed surfaces of the sacrificial gate structures 130 and the stack of semiconductor layers 104, and a portion of the exposed surfaces of the substrate 101, as shown in FIG. 11. The base layer 107 may be conformally formed on the top surface and sidewall surfaces of the sacrificial gate structures 130. In some embodiments, the base layer 107 is deposited so that the base layer 107 on the horizontal surfaces of the semiconductor device structure 100, such as the top surface of the sacrificial gate structures 130 and the top surface of the substrate 101, has a rounded head or curved (e.g., convex) profile. As will be discussed in more detail below, the base layer 107 is deposited such that it does not fully cover the top surface of the substrate 101 between the neighboring sacrificial gate structures 130, leaving the top surface of the substrate 101 at and/or near the corner of the substrate 101 and the sidewall surface of the stack of semiconductor layers 104 (e.g., the sidewall of the bottommost dielectric spacer 144) exposed to air. The base layer 107 on the top surface of the sacrificial gate structures 130 may have a thickness H0, the base layer 107 on the sidewall surfaces of the sacrificial gate structures 130 and the stack of semiconductor layers 104 may have a thickness H1 less than the thickness H0, and the base layer 107 on the top surface of the substrate 101 has a thickness H2 greater than the thickness H0.

In some embodiments, the base layer 107 is deposited such that a highest point (e.g., center point) of the base layer 107 on the top surface of the substrate 101 is at an elevation higher than an interface 109 defined by the bottommost first semiconductor layer 106 and dielectric spacer 144. In some embodiments, the highest point of the base layer 107 on the top surface of the substrate 101 is at an elevation between a top surface and a bottom surface of the bottommost first semiconductor layer 106.

In some embodiments, the base layer 107 is deposited such that a highest point (e.g., center point) of the base layer 107 on the top surface of the substrate 101 is at an elevation substantially the same as the interface 109 defined by the bottommost first semiconductor layer 106 and dielectric spacer 144.

The base layer 107 may include or be formed of silicon. In some embodiments, the base layer 107 is pure silicon (e.g., intrinsic or undoped) or substantially pure silicon (e.g., substantially free from impurities, for example, with a percentage of impurity lower than about 1 percent). In some embodiments, the base layer 107 is formed of a doped silicon. In cases where the base layer 107 is a doped silicon, the dopant of a group III element, such as boron, may be used. In one exemplary embodiment, the base layer 107 is undoped silicon.

The base layer 107 may be deposited using any suitable deposition process, such as CVD, cyclic deposition etch (CDE) epitaxy process, selective etch growth (SEG) process, ALD, PEALD, molecular beam epitaxy (MBE), or any combination thereof. In some embodiments, the base layer 107 is deposited by a plasma-assisted CVD process using a bottom-up growth technique. The bottom-up growth technique may be an epitaxial growth process that incorporates an etch component (e.g., a deposition-etch process). In such cases, the semiconductor device structure 100 may be simultaneously exposed to both deposition and etch chemistry during the epitaxial growth process. In cases where the base layer 107 is formed of undoped silicon, the bottom-up growth process may be performed by exposing the semiconductor device structure 100 to plasma species formed from silicon-containing precursor(s) and an etching gas. The silicon-containing precursor deposits silicon on exposed surfaces of the sacrificial gate structures 130 and the stack of semiconductor layers 104, and a portion of the exposed surfaces of the substrate 101, while the etching gas etches away a portion of the deposited silicon. Suitable silicon-containing precursor may include, but is not limited to, monosilane (SiH₄), disilane (Si₂H₆), trisilane (Si₃H₈), tetrasilane (Si₄H₁₀), dimethylsilane ((CH₃)₂SiH₂), methylsilane (SiH(CH₃)₃), dichlorosilane (SiH₂Cl₂, DCS), trichlorosilane (SiHCl₃, TCS), or the like. Suitable etching gases may include, but are not limited to, hydrogen, hydrogen chloride (HCl), a chlorine gas (Cl₂), or the like.

In any case, the net result of the deposition-etch process forms a conformal layer of the base layer 107 on the exposed surfaces of the sacrificial gate structures 130 and the stack of semiconductor layers 104, and a portion of the exposed surfaces of the substrate 101. Since the ion flux at the horizontal surfaces of the semiconductor device structure 100 (e.g., top surfaces of the sacrificial gate structure 130 and the substrate 101) is typically higher than the ion flux at the vertical surfaces of the semiconductor device structure 100 (e.g., sidewall surfaces of the sacrificial gate structures 130 and the stack of semiconductor layers 104), the base layer 107 on the horizontal surfaces is deposited with a greater thickness than the vertical surfaces of the semiconductor device structure 100. In addition, the difference of the ion flux between the horizontal and vertical surfaces yields a greater deposition rate than the etching rate at the horizontal surfaces of the semiconductor device structure 100, thereby depositing the base layer 107 in a bottom-up fashion with bottom-to-sidewall thickness difference.

In various embodiments, the base layer 107 on the horizontal surfaces of the semiconductor device structure 100 (e.g., top surfaces of the sacrificial gate structure 130 and the substrate 101) is deposited with a rounded head or top. The rounded head or curved (e.g., convex) profile of the top of the base layer 107 may be a result of lower ion flux at and/or near the sidewall surfaces of the stack of semiconductor layers 104 than the center region of the horizontal surfaces of the semiconductor device structure 100. It has been observed that an increased deposition rate of the base layer 107 can promote the rounded or curved profile of the top of the base layer 107. The deposition rate can be enhanced by, for example, increasing the power of an RF generator (for plasma generation), reducing the chamber pressure, providing a bias power to a substrate support on which the semiconductor device structure 100 is disposed, and/or other process parameters, such as temperature, deposition gas flow, etching gas flow, carrying gas flow, and combinations thereof, may be adjusted to increase the deposition rate, and thus the shape/height of the base layer 107. In some embodiments, the process parameters of the bottom-up growth process are controlled such that lower presence of ion flux is provided at the corner region between the sidewall surfaces of the stack of semiconductor layers 104 and the top surface of the substrate 101. Therefore, there is little or no coverage of the base layer 107 in the corner region of the top surface of the substrate 101 between the neighboring sacrificial gate structures 130. In such cases, a gap 113 may be formed at a corner between the base layer 107 on the sidewall surfaces of the stack of semiconductor layers 104 and the base layer 107 on the substrate 101, leaving a portion of the top surface of the substrate 101 exposed to air.

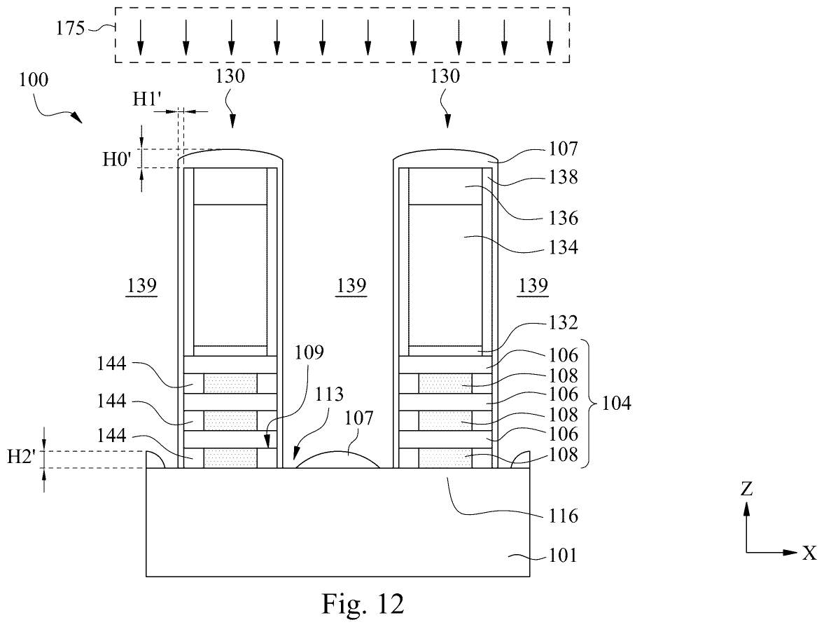

At block 1024, the semiconductor device structure 100 is subjected to a trimming process 175 to remove a portion of the base layer 107, as shown in FIG. 12. The trimming process 175 may be performed in an isotropic manner such that the base layer 107 on the top and sidewall surfaces of the sacrificial gate structures 130 and the stack of semiconductor layers 104 is reduced in thickness. For example, the base layer 107 on the top surface of the sacrificial gate structures 130 is reduced from the thickness H0 (FIG. 11) to H0′, and the base layer 107 on the sidewall surfaces of the sacrificial gate structures 130 and the stack of semiconductor layers 104 is reduced from the thickness H1 (FIG. 11) to H1′. In some embodiments, the thickness of the base layer 107 on the top surface of the substrate 101 is reduced from H2 (FIG. 11) to H2′. The gap 113 at a corner between the base layer 107 on the sidewall surfaces of the stack of semiconductor layers 104 and the base layer 107 on the substrate 101 is widened after the trimming process 175.

In some embodiments, the base layer 107 is trimmed such that the highest point (e.g., center point) of the base layer 107 on the top surface of the substrate 101 is at an elevation higher than the interface 109 defined by the bottommost first semiconductor layer 106 and dielectric spacer 144. In some embodiments, the highest point of the base layer 107 on the top surface of the substrate 101 is at an elevation between the top surface and the bottom surface of the bottommost first semiconductor layer 106.

In some embodiments, the base layer 107 is trimmed such that the highest point (e.g., center point) of the base layer 107 on the top surface of the substrate 101 is at an elevation slightly below than the interface 109 defined by the bottommost first semiconductor layer 106 and dielectric spacer 144.

In some embodiments, the trimming process 175 is a wet etch process using NH₄OH, HF or diluted HF, deionized (DI) water, tetramethylammonium hydroxide (TMAH), other suitable solution, or a combination thereof. In some embodiments, the trimming process 175 may be a standard clean-2 (SC2) followed by a standard clean-1 (SC1), where the SC2 is a mixture of DI water, hydrochloric (HCl) acid, and hydrogen peroxide (H₂O₂), and the SC1 is a mixture of D1 water, NH₄OH, and H₂O₂. In some embodiments, an isopropyl alcohol (IPA) may be used after the SC1. Other suitable wet etch process, such as an APM process, which includes at least water (H₂O), ammonium hydroxide (NH₄OH), and hydrogen peroxide (H₂O₂), a HPM process, which includes at least H₂O, H₂O₂, and hydrogen chloride (HCl), a SPM process (also known as piranha clean), which includes at least H₂O₂ and sulfuric acid (H₂SO₄), or any combination thereof, may also be used.

In some embodiments, the trimming process 175 is a dry etch process using plasma or a radical of species. For example, the trimming process 175 may use reactive species generated from hydrogen-containing gases in-situ in a reaction chamber or in the upstream of a reaction chamber (e.g., from a remote plasma generator). In some embodiments, the trimming process 175 is a plasma treatment process. Exemplary reactive species may include hydrogen plasma or neutral radical species, such as hydrogen radicals or atomic hydrogen. Other chemistry such as chlorine-containing gases may also be used. The plasma treatment may be any suitable plasma process, such as a decoupled plasma process, a remote plasma process, or a combination thereof. The plasma may be formed by a capacitively coupled plasma (CCP) source or an inductively coupled plasma (ICP) source driven by an RF power generator.

In cases where ICP source is used, the plasma treatment may be performed in a remote plasma generator having a chamber wall, a ceiling, and a plasma source power applicator comprising a coil antenna disposed over the ceiling and/or around the chamber wall. The plasma source power applicator is coupled through an impedance match network to an RF power source, which may use a continuous wave RF power generator or a pulsed RF power generator operating on a predetermined duty cycle. The source power ionizes the hydrogen-containing gases supplied to the remote plasma generator. The generated hydrogen ions may be filtered by a grounded showerhead disposed in the remote plasma generator to generate neutral radical species (e.g., hydrogen radicals) prior to supplying to a process chamber in which the semiconductor device structure 100 is disposed. In one exemplary embodiment, the decoupled plasma process is formed by the ICP source driven by the RF power generator using a tunable frequency ranging from about 2 MHz to about 13.56 MHz, and the chamber is operated at a pressure in a range of about 0.5 Torr to about 8 Torr and a temperature of about 300 degrees Celsius to about 600 degrees Celsius for a process time of about 3 seconds to about 50 seconds. The flow of the processing gas (e.g., hydrogen-containing gas) may be provided at about 200 sccm to about 5000 sccm. The RF power generator is operated to provide power between about 50 watts to about 1000 watts, and the output of the RF power generator is controlled by a pulse signal having a duty cycle in a range of about 20% to about 80%. In cases where the base layer 107 is formed of silicon, a portion of the base layer 107 may be converted into hydrogenated amorphous silicon and removed by the plasma or neutral radical species.

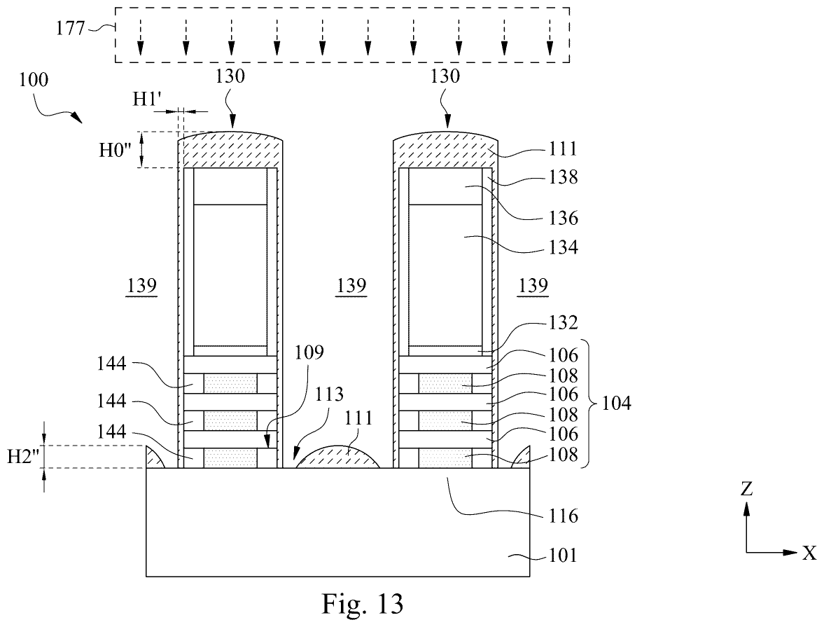

At block 1026, the semiconductor device structure 100 is subjected to a treatment process 177 to convert a portion of the trimmed base layer 107 into a sacrificial layer 111, as shown in FIG. 13. After the treatment process 177, the thickness of the sacrificial layer 111 may be increased. For example, the base layer 107 on the top surface of the sacrificial gate structures 130 is increased from the thickness H0′ (FIG. 12) to H0″, the base layer 107 on the sidewall surfaces of the sacrificial gate structures 130 and the stack of semiconductor layers 104 is increased from the thickness H1′ (FIG. 12) to H1″. In some embodiments, the thickness of the base layer 107 on the top surface of the substrate 101 is increased from H2′ (FIG. 12) to H2″. The gap 113 at a corner between the base layer 107 on the sidewall surfaces of the stack of semiconductor layers 104 and the base layer 107 on the substrate 101 remains open after the treatment process 177.

In some embodiments, the base layer 107 is treated such that the highest point (e.g., center point) of the resulting sacrificial layer 111 on the top surface of the substrate 101 is at an elevation higher than the interface 109 defined by the bottommost first semiconductor layer 106 and dielectric spacer 144. In some embodiments, the highest point of the resulting sacrificial layer 111 on the top surface of the substrate 101 is at an elevation between the top surface and the bottom surface of the bottommost first semiconductor layer 106.

In some embodiments, the base layer 107 is treated such that the highest point (e.g., center point) of the resulting sacrificial layer 111 on the top surface of the substrate 101 is at an elevation substantially the same as the interface 109 defined by the bottommost first semiconductor layer 106 and dielectric spacer 144.

In various embodiments, the treatment process 177 may be a nitridation process using plasma or a radical of species. For example, the treatment process 177 may use reactive species generated from nitrogen-containing gases in-situ in a reaction chamber or in the upstream of a reaction chamber (e.g., from a remote plasma generator). In some embodiments, the treatment process 177 is a plasma treatment process. Exemplary reactive species may include nitrogen plasma or neutral radical species, such as nitrogen radicals or atomic nitrogen. Alternatively, the treatment process 177 may be an oxidation process. In such cases, the treatment process 177 may use reactive species (e.g., oxygen plasma, oxygen radicals or atomic oxygen) generated from an oxygen-containing gases. Additionally or alternatively, the treatment process 177 may be a combination of a nitridation process and an oxidation process. The plasma treatment may be any suitable plasma process, such as a decoupled plasma process, a remote plasma process, or a combination thereof. The plasma may be formed by a CCP source or an ICP source driven by an RF power generator.

In cases where ICP source is used, the plasma treatment may be performed in a remote plasma generator. Likewise, the plasma source power may use a continuous wave RF power generator or a pulsed RF power generator operating on a predetermined duty cycle. The source power ionizes the nitrogen-containing or oxygen-containing gases supplied to the remote plasma generator. The generated nitrogen or oxygen ions may be filtered to generate neutral radical species (e.g., nitrogen radicals) prior to supplying to the process chamber in which the semiconductor device structure 100 is disposed. In one exemplary embodiment, the decoupled plasma process is formed by the ICP source driven by the RF power generator using a tunable frequency ranging from about 2 MHz to about 13.56 MHz, and the chamber is operated at a pressure in a range of about 0.5 Torr to about 8 Torr and a temperature of about 300 degrees Celsius to about 600 degrees Celsius for a process time of about 3 seconds to about 50 seconds. The flow of the processing gas (e.g., nitrogen-containing gas) may be provided at about 200 sccm to about 5000 sccm. Suitable nitrogen-containing gas may include, but is not limited to, nitrogen gas (N₂), ammonia (NH₃), nitrous oxide (N₂O), or the like. Suitable oxygen-containing gas may include, but is not limited to, oxygen gas (O₂), ozone (O₃), or water vapor. The RF power generator is operated to provide power between about 50 watts to about 1000 watts, and the output of the RF power generator is controlled by a pulse signal having a duty cycle in a range of about 20% to about 80%. In cases where the base layer 107 is formed of silicon, the base layer 107 may be partially or fully converted into silicon nitride or silicon oxide, depending on the processing gas used during the treatment process 177.

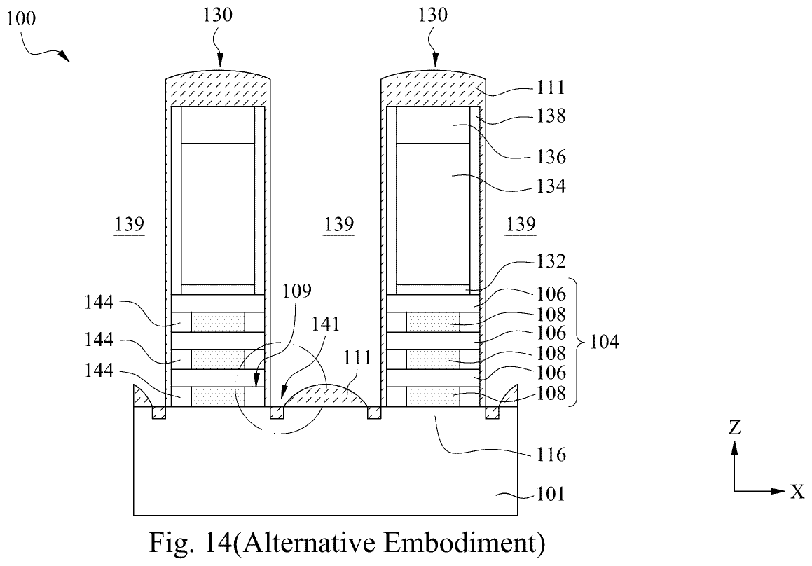

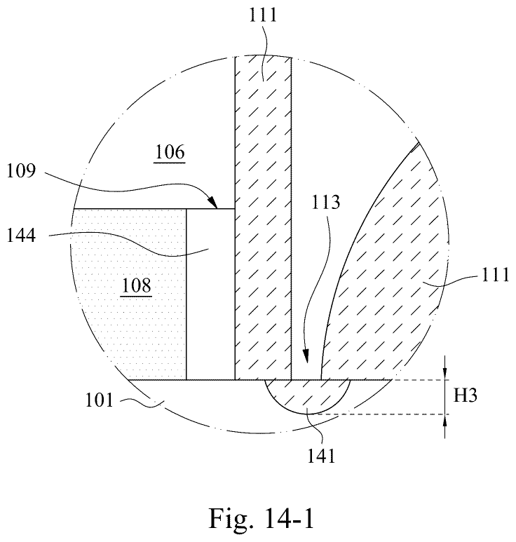

In some embodiments, which can be combined with any one or more embodiments of this disclosure, the surface portion of the substrate 101 exposed through the gap 113 is nitridized or oxidized and forms a nitridized or oxidized region 141 after the treatment process 177, as shown in FIG. 14. In cases where the substrate 101 is formed of silicon, the nitridized or oxidized region 141 may contain silicon nitride or silicon oxide. The nitridized or oxidized region 141 may extend a thickness into the substrate 101. In some embodiments, the nitridized or oxidized region 141 may have a depth H3 in a range of about 0.5 nm to about 10 nm. FIG. 14-1 is an enlarged view of a portion of the semiconductor device structure 100 showing the nitridized or oxidized region 141 after the treatment process 177. The nitridized or oxidized region 141 may extend radially in the substrate 101 and in contact with a portion of the bottom surface of the base layer 107 contacting the dielectric spacer 144 and a portion of the bottom surface of the base layer 107 contacting the substrate 101.

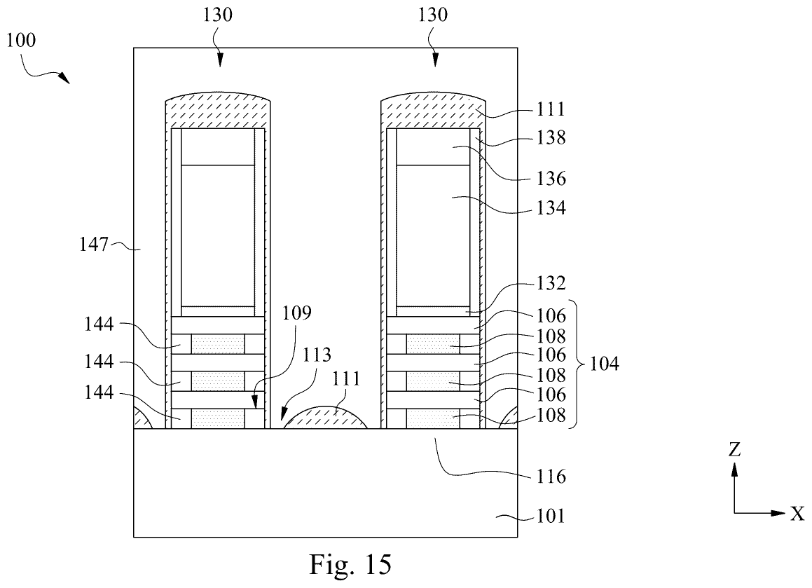

At block 1028, a protection layer 147 is formed on the sacrificial layer 111, as shown in FIG. 15. The protection layer 147 may be a polymer, a spin-on carbon material, or other suitable photoresist layer. The protection layer 147 protects the lower portion of the sacrificial layer 111 (particularly the sacrificial layer 111 on the substrate 101) from being damaged during the subsequent etch back process. The protection layer 147 may be deposited until it overfills the recess 139 (FIG. 13) between the neighboring sacrificial gate structures 130. The protection layer 147 may be deposited using a spin-on coating or any suitable deposition process.

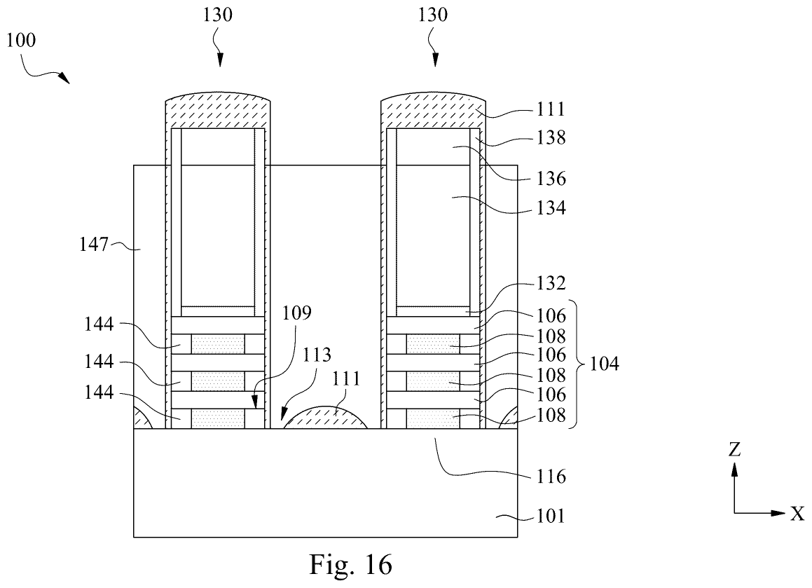

At block 1030, an etch back process is performed to remove a portion of the protection layer 147, as shown in FIG. 16. The protection layer 147 may be recessed until an upper portion of the sacrificial layer 111 is exposed. In some embodiments, the protection layer 147 is recessed so that a top of the protection layer 147 is at an elevation substantially at or slightly below an interface defined by the mask layer 136 and the sacrificial gate electrode layer 134. The etch back process may be a selective etch process that removes the protection layer 147 but does not remove the sacrificial layer 111. Since the sacrificial layer 111 on the top surface of the sacrificial gate structures 130 has a greater thickness than that of the sacrificial layer 111 on the sidewall surfaces of the sacrificial gate structures 130 and the stack of semiconductor layers 104, a longer etch time may be required. The use of the protection layer 147 ensures the sacrificial layer 111 on the upper portion of the sacrificial gate structures 130 is fully removed without substantially affecting the sacrificial gate structures 130 and the sacrificial layer 111 on the substrate 101. In some embodiments, the protection layer 147 may be recessed so that a top of the protection layer 147 is at an elevation slightly above an upper surface of the bottommost first semiconductor layer 106.

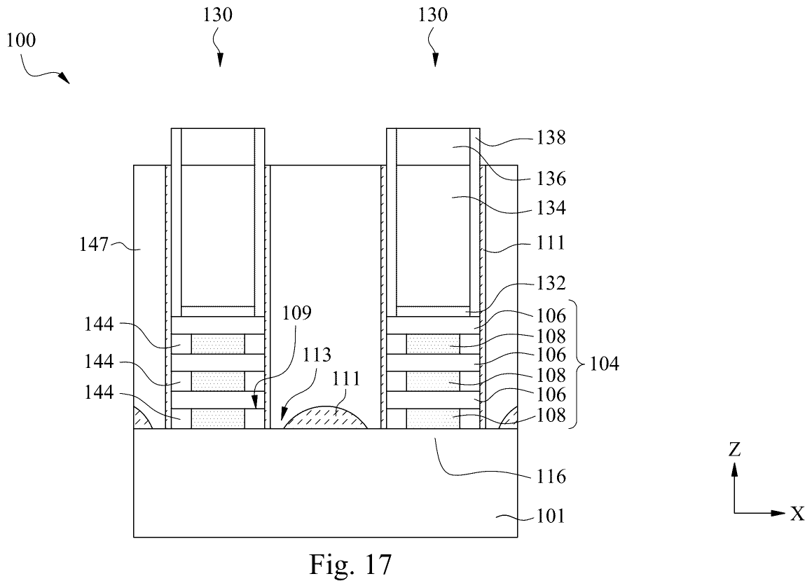

At block 1032, the exposed sacrificial layer 111 on the upper portion of the sacrificial gate structures 130 is removed, as shown in FIG. 17. The sacrificial layer 111 may be removed using any suitable removal process, such as a wet etch, a dry etch, or a combination thereof. The removal process is performed to selectively remove the sacrificial layer 111 not covered by the protection layer 147. The removal process may be a selective etch process that removes the sacrificial layer 111 but not the sacrificial gate structures 130 and the protection layer 147. Depending on the material of the sacrificial layer 111, the removal process may include a hot phosphoric acid (H₃PO₄) solution to remove silicon nitride, or a HF solution to remove silicon oxide, for example.

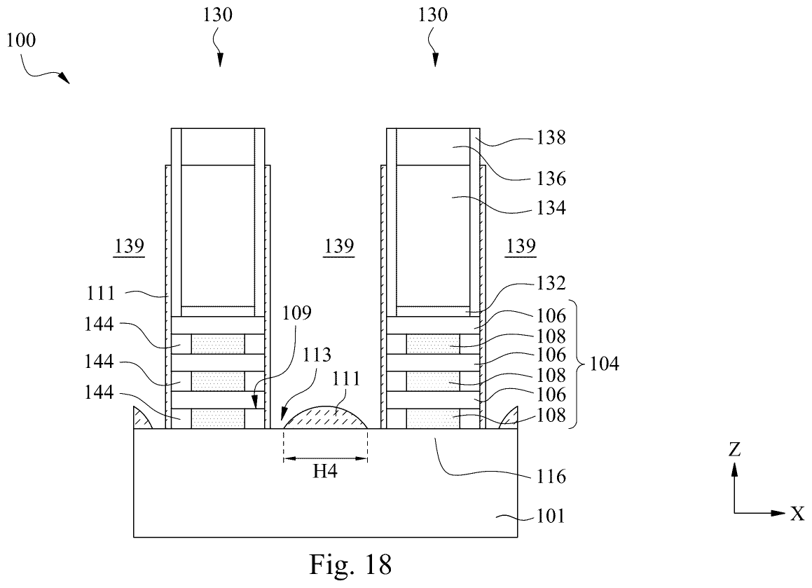

At block 1034, the remaining protection layer 147 is removed, as shown in FIG. 18. Upon removal of the protection layer 147, the recess 139 and the gap 113 are revealed, and the sacrificial layer 111 on the sidewall surfaces of the sacrificial gate structures 130, the sidewall surfaces of the stack of semiconductor layers 104, and the sacrificial layer 111 on the substrate 101 are exposed. At this stage, the sacrificial layer 111 has a width H4. The protection layer 147 may be removed by ashing or any suitable process.

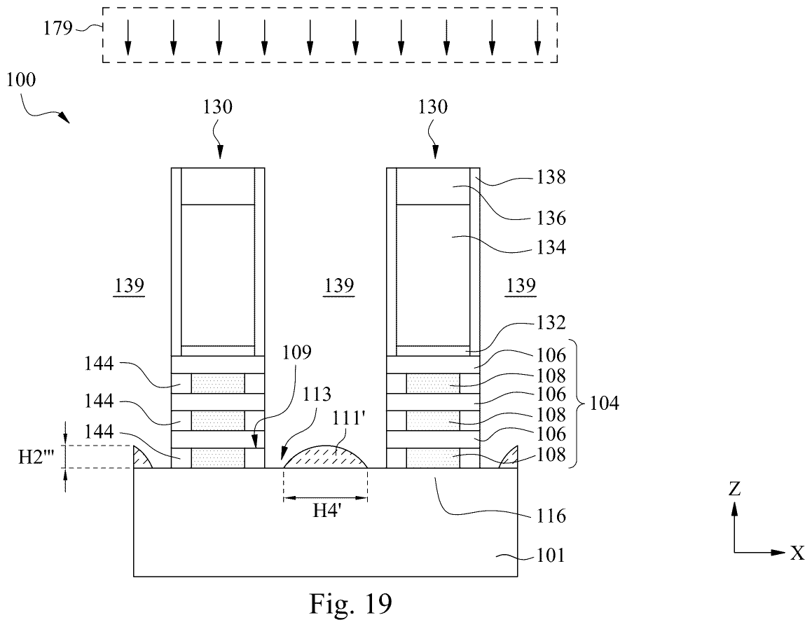

At block 1036, the sacrificial layer 111 on the sidewall surfaces of the sacrificial gate structures 130 and the sidewall surfaces of the stack of semiconductor layers 104 is removed, as shown in FIG. 19. The removal of the sacrificial layer 111 may be done by an etch process 179, which can be a wet etch, a dry etch, or a combination thereof. The etch process 179 may be a selective etch process that removes the sacrificial layer 111 but not the sacrificial gate structures 130, the first semiconductor layers 106, and the dielectric spacers 144. A portion of the sacrificial layer 111 on the top surface of the substrate 101 may also be removed. However, due to the high aspect ratio of the recess 139, the sacrificial layer 111 on the substrate 101 is etched at a slower rate than the sacrificial layer 111 on the sidewall surfaces of the sacrificial gate structures 130 and the sidewall surfaces of the stack of semiconductor layers 104. The etch process 179 may be performed until the sacrificial layer 111 on the sidewall surfaces of the sacrificial gate structures 130 and the sidewall surfaces of the stack of semiconductor layers 104 is removed, exposing the bottommost dielectric spacers 144. The sacrificial layer 111 remains on the top surface of the substrate 101 after the etch process 179 becomes a supporting layer 111′. The supporting layer 111′ has a rounded head or curved (e.g., convex) top profile that follows the shape of the sacrificial layer 111 on the substrate 101. The supporting layer 111′ has a height or thickness H2′″ less than the thickness H2″. In some embodiments, the thickness H2′″ is less than about 8 nm, for example about 4 nm to about 6 nm. The supporting layer 111′ has a width H4′ that is reduced from the width H4 shown in FIG. 18.

In some embodiments, the supporting layer 111′ is etched such that a highest point (e.g., center point) of the supporting layer 111′ on the top surface of the substrate 101 is at an elevation higher than the interface 109 defined by the bottommost first semiconductor layer 106 and dielectric spacer 144. In some embodiments, the highest point of the supporting layer 111′ on the top surface of the substrate 101 is at an elevation between a top surface and a bottom surface of the bottommost first semiconductor layer 106. In any case, the presence of the supporting layer 111′ helps to prevent the subsequent source/drain feature from filling in the space between the substrate 101 and the source/drain feature, thereby maintaining the gap 113 at the corner of the bottommost dielectric spacer 144 and the substrate 101 during formation of the epitaxial source/drain features 146. The use of the supporting layer 111′ is helpful especially when the recess 139 has a high aspect ratio.

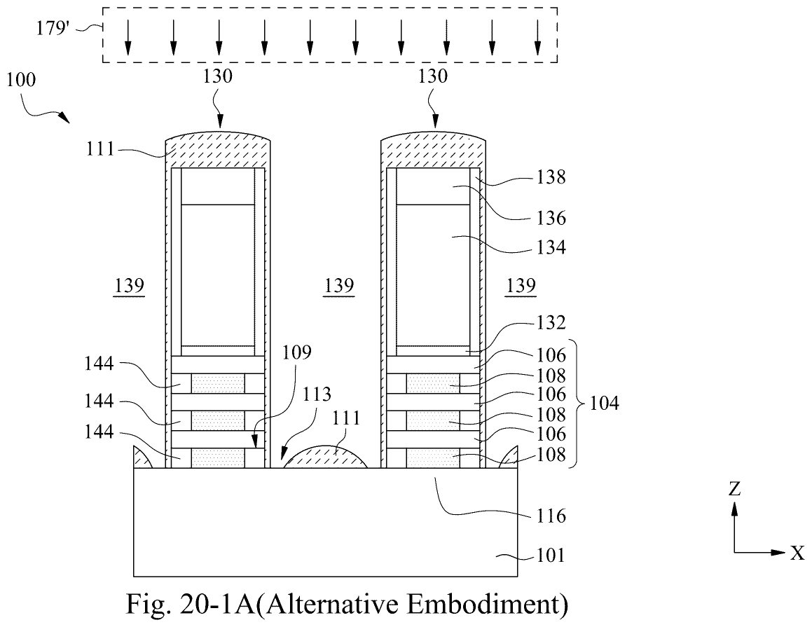

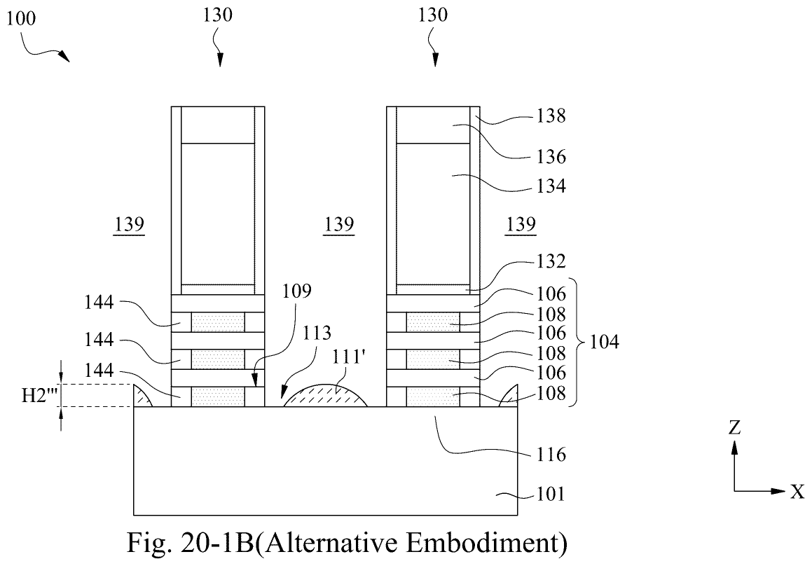

The embodiments shown in FIGS. 15-19 above illustrate a removal scheme in which the sacrificial layer 111 on the sidewall surfaces of the sacrificial gate structures 130 and the stack of semiconductor layers 104 is removed in a two-step process involving the use of a protection layer (e.g., the protection layer 147). In an alternative embodiment shown in FIGS. 20-1A and 20-1B, after the base layer 107 is converted into the sacrificial layer 111, the sacrificial layer 111 is subjected to an etch process without the use of the protection layer. In such a case, an etch process 179′, which may be a directional isotropic etching process, is used to remove the sacrificial layer 111 on the sidewall surfaces of the sacrificial gate structures 130 and the stack of semiconductor layers 104, as well as the sacrificial layer 111 on the substrate 101. Due to the high aspect ratio of the recess 139, the sacrificial layer 111 on the top and sidewall surfaces of the sacrificial gate structures 130 and the sidewall surfaces of the stack of semiconductor layers 104 is removed at a greater etching rate than that of the sacrificial layer 111 on the substrate 101. Likewise, the sacrificial layer 111 remains on the top surface of the substrate 101 after the etch process 179′ becomes a supporting layer 111′, as shown in FIG. 20-1B. The supporting layer 111′ has a rounded head or curved (e.g., convex) profile that generally follows the shape of the sacrificial layer 111 on the substrate 101 prior to the etch process 179′. The supporting layer 111′ has a thickness H2′″ less than the thickness H2″. In some embodiments, the thickness H2′″ is less than about 8 nm, for example about 4 nm to about 6 nm.

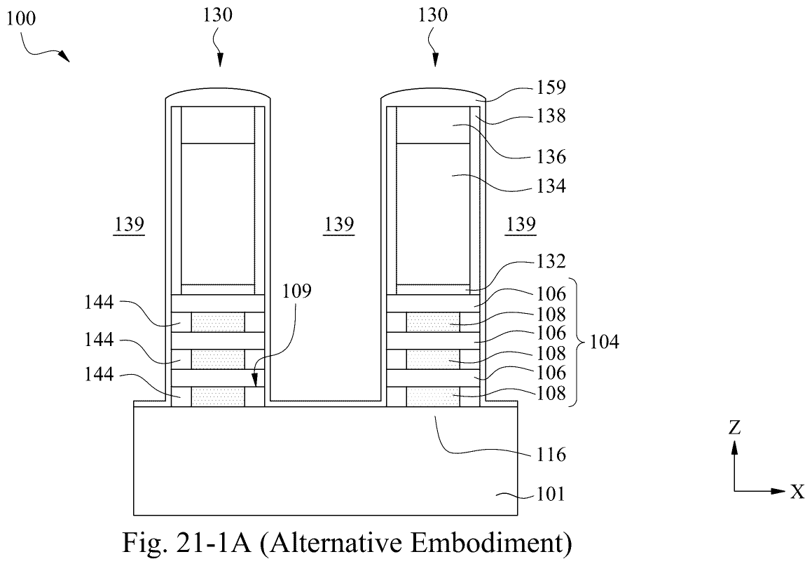

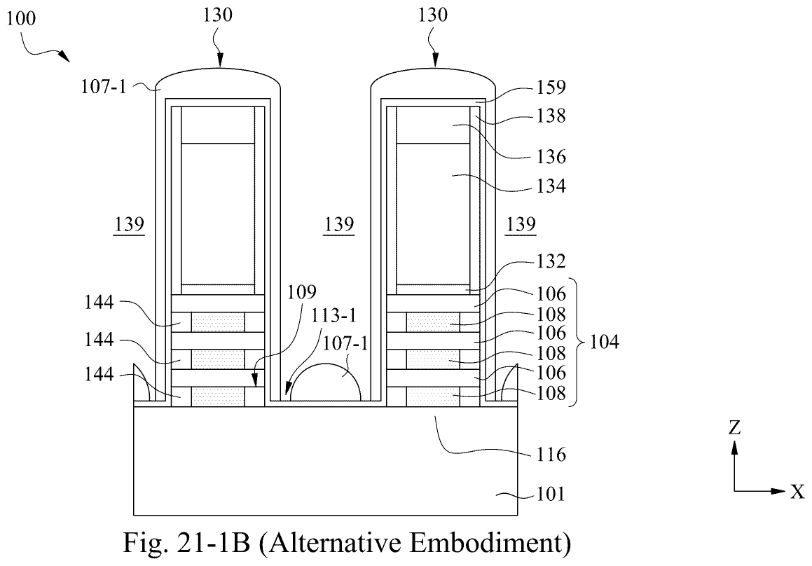

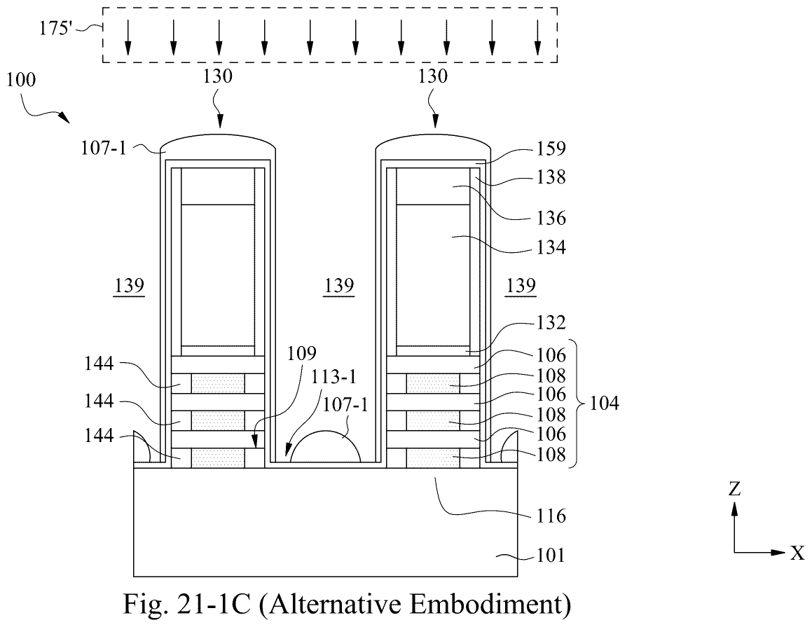

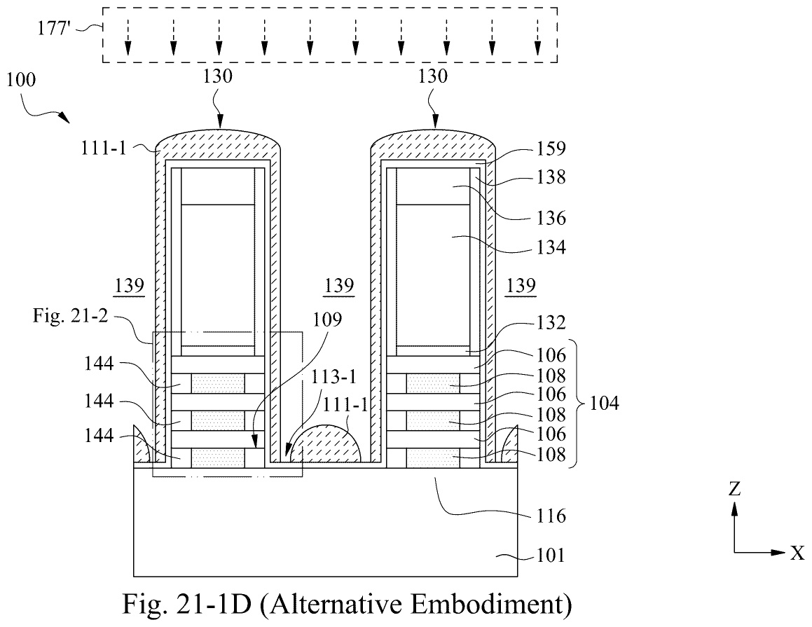

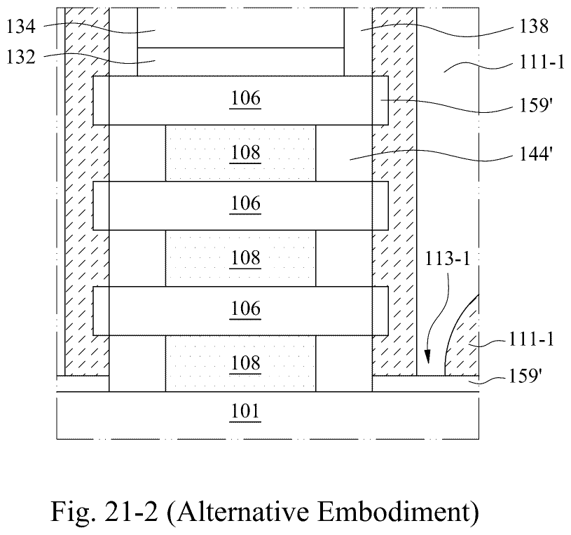

FIGS. 21-1A to 21-1D illustrate cross-sectional side views of various stages of manufacturing the semiconductor device structure, in accordance with some alternative embodiments. In FIG. 21-1A, prior to forming the base layer 107, a liner 159 is formed on the exposed surfaces of the sacrificial gate structures 130 and the stack of semiconductor layers 104, and a portion of the exposed surfaces of the substrate 101. In some embodiments, the liner 159 is an oxygen-containing layer, such as silicon oxide (SiOₓ) or the like. In some embodiments, the liner 159 is a semiconductor layer, such as a doped silicon. The liner 159 may be a conformal layer formed by a conformal process, such as an ALD process, a PECVD process, a molecular-beam deposition (MBD) process, or the like, or a combination thereof. The liner 159 may have a thickness in a range of about 0.5 nm to about 3 nm. The liner 159 serves as a cap layer and can be used to protect the channel layers (e.g., first semiconductor layers 106) during the subsequent processes.

In FIG. 21-1B, a base layer 107-1, such as the base layer 107 discussed above with respect to FIG. 11, is formed on the liner 159. The base layer 107-1 may be formed in a similar fashion to the base layer 107 such that the base layer 107-1 adjacent the bottommost dielectric spacer 144 and the base layer 107-1 over the substrate 101 are separated from each other by a gap 113-1.

In FIG. 21-1C, the base layer 107-1 is subjected to a trimming process 175′, such as the trimming process 175, to remove a portion of the base layer 107-1. Likewise, the trimming process 175′ may be performed in a similar fashion to the trimming process 175 such that the base layer 107-1 over the top and sidewall surfaces of the sacrificial gate structures 130 and the stack of semiconductor layers 104 is reduced in thickness. The thickness of the base layer 107-1 over the top surface of the substrate 101 is also reduced, and the gap 113-1 is widened after the trimming process 175′. The liner 159 protects the semiconductor device structure 100 during the trimming process 175′.

In FIG. 21-1D, the semiconductor device structure 100 is subjected to a treatment process 177′, such as the treatment process 177, to convert a portion of the trimmed base layer 107-1 into a sacrificial layer 111-1. The liner 159 protects the first semiconductor layers 106 from converting during the treatment process 177′. Likewise, after the treatment process 177′, the thickness of the sacrificial layer 111-1 may be increased, and the gap 113-1 at a corner between the base layer 107-1 on the sidewall surfaces of the stack of semiconductor layers 104 and the base layer 107-1 on the substrate 101 remains open after the treatment process 177′. The base layer 107-1 may be treated such that the highest point (e.g., center point) of the resulting sacrificial layer 111′ on the top surface of the substrate 101 is at an elevation higher than the interface 109 defined by the bottommost first semiconductor layer 106 and dielectric spacer 144. In some embodiments, the highest point of the resulting sacrificial layer 111′ on the top surface of the substrate 101 is at an elevation between the top surface and the bottom surface of the bottommost first semiconductor layer 106.

While not shown, various processes, such as those discussed above with respect to FIG. 15-19 or 20-1A, can be performed after the sacrificial layer 111-1 is formed to remove portions of the sacrificial layer 111-1 from the sacrificial gate structures 130 and the stack of the semiconductor layers 104, leaving the sacrificial layer 111-1 (later become the supporting layer) on the top surface of the substrate 101, as shown in FIGS. 19 and 20-1B. One or more etch processes may be performed to further remove the exposed liner 159. In some embodiments, the one or more etch processes are performed such that the liner 159 not covered by the sacrificial layer 111-1 is removed. In some embodiments, the one or more etch processes are performed such that only the liner 159 in contact with the bottommost dielectric spacer 144 and the substrate 101 remains.

FIG. 21-2 illustrates an enlarged view of a portion of the semiconductor device structure 100 in FIG. 21-1D, in accordance with some alternative embodiments. The embodiment shown in FIG. 21-2 is similar to the embodiment shown in FIGS. 21-1A to 21-1D except that a liner 159′ is selectively formed on the sidewall surface of the first semiconductor layer 106 and the well portion 116 of the substrate 101. The liner 159′ may be made of any suitable material that can retard a chemical reaction during subsequent conversation of the base layer 107-1 into the sacrificial layer 111-1. The liner 159′ may have a thickness in a range of about 0.5 nm to about 3 nm. The liner 159′ may be made of a material that is chemically different than the first semiconductor layer 106 and the subsequent base layer 107-1. In some embodiments, the liner 159′ is a semiconductor material. In some embodiments, the liner 159′ is a dielectric material. In cases where the liner 159′ is formed of a semiconductor material, such as a doped silicon, the dopant of a group III element, such as boron, may be used. In one exemplary embodiment, the liner 159′ is a boron-doped silicon (Si:B). The use of Si:B as the liner 159′ may be advantageous because the boron dopants may alter crystal orientation of the underlying materials (e.g., first semiconductor layers 106 and the well portion 116 of the substrate 101) to promote growth of the subsequent base layer 107-1 on the liner 159′. The liner 159′ may be selectively formed using any suitable selective deposition process, such as cyclic deposition etch (CDE) epitaxy process or selective etch growth (SEG). The precursors and the temperature for forming the liner 159′ can be controlled to achieve selective or preferential growth of the liner layer 159′ on the semiconductor surfaces of the first semiconductor layers 106 over the dielectric surfaces of the dielectric spacers 144.

In cases where the liner 159′ is formed of a dielectric material, the selective deposition of the liner 159′ may be achieved by first globally formed on the exposed surfaces of the semiconductor device structure 100 by an ALD process, followed by one or more selective etch processes (e.g., plasma treatment or atomic layer etch (ALE)) to remove the liner 159′ from the dielectric spacers 144, leaving the liner 159′ on the first semiconductor layers 106. Suitable dielectric materials for the liner 159′ may include, but are not limited to, SiN, SiCN, SiON, SiOCN, or any suitable nitride-based dielectrics.

Thereafter, the base layer 107-1 is formed on the exposed surfaces of the semiconductor device structure 100 and covers the liner 159′, and then the base layer 107-1 is subjected to a treatment process to convert the base layer 107-1 into the sacrificial layer 111-1 in a similar fashion to those discussed above with respect to FIGS. 11-13. Various processes, such as those discussed above with respect to FIG. 15-19 or 20-1A, are performed to remove portions of the sacrificial layer 111-1 from the sacrificial gate structures 130 and the stack of the semiconductor layers 104, leaving the sacrificial layer 111-1 (later become the supporting layer) on the top surface of the substrate 101, as shown in FIGS. 19 and 20-1B.

At block 1038, an epitaxial S/D feature 146 is formed on the supporting layer 111′ in the source/drain (S/D) regions, as shown in FIGS. 22A-22D. The second semiconductor layer 108 under the sacrificial gate structure 130 are separated from the epitaxial S/D features 146 by the dielectric spacers 144. The epitaxial S/D feature 146 may include one or more layers of Si, SiP, SiC and SiCP for an n-type FET or Si, SiGe, Ge for a p-type FET. The epitaxial S/D features 146 may be formed by an epitaxial growth method using selective epitaxial growth (SEG), CVD, ALD or MBE. The epitaxial S/D features 146 may be the S/D regions. For example, one of a pair of epitaxial S/D features 146 located on one side of the sacrificial gate structures 130 may be a source region, and the other of the pair of epitaxial S/D features 146 located on the other side of the sacrificial gate structures 130 may be a drain region. A pair of S/D epitaxial features 146 includes a source epitaxial feature 146 and a drain epitaxial feature 146 connected by the channels (i.e., the first semiconductor layers 106). Source/drain region(s) may refer to a source or a drain, individually or collectively dependent upon the context. In this disclosure, a source and a drain are interchangeably used, and the structures thereof are substantially the same.

The epitaxial S/D features 146 may grow laterally from the sidewall of the first semiconductor layers 106. The epitaxial S/D features 146 of a fin structure may merge with the epitaxial S/D features 146 of the neighboring fin structures and form an integrated body. The epitaxial S/D features 146 may grow both vertically and horizontally to form facets, which may correspond to crystalline planes of the material used for the first semiconductor layers 106. After the epitaxial growth, an upper portion of the supporting layer 111′ may be in contact with or covered by the epitaxial S/D feature 146. The bottom surface 146b of each epitaxial S/D feature 146 may have a concave shape or curved surface depending on the profile of the supporting layer 111′.

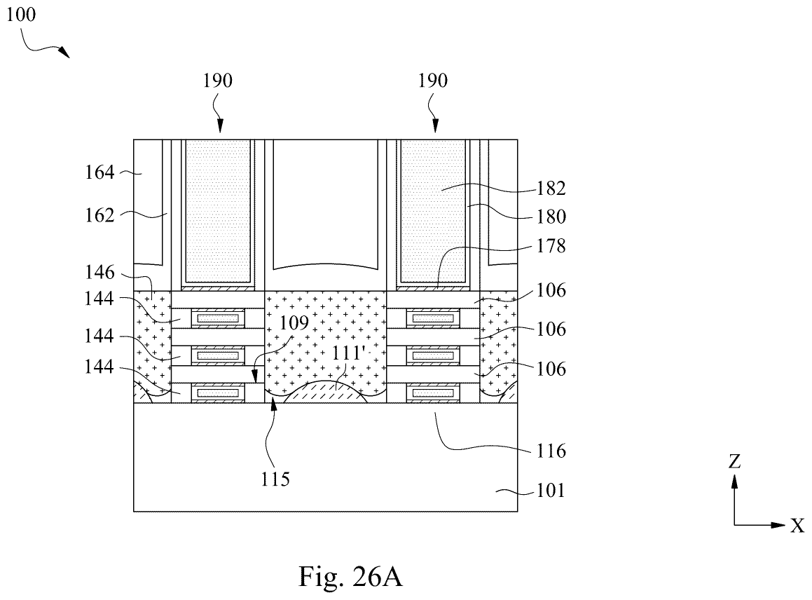

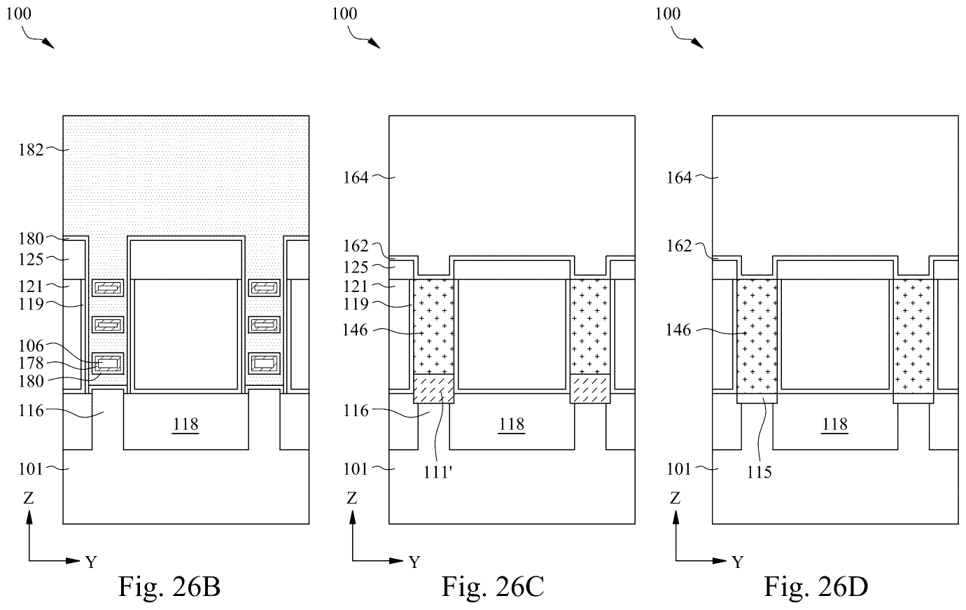

FIG. 22A-1 illustrates an enlarged view of a portion of the semiconductor device structure 100 shown in FIG. 22A. In some embodiments, the bottom surface 146b of the epitaxial S/D feature 146 may have a first section 146-1 and a second section 146-2 surrounding the first section 146-1. The first section 146-1 is a curved surface having a first curvature and the second section 146-2 is a curved surface having a second curvature. In some embodiments, the first curvature is different than the second curvature. In some embodiments, the first curvature is opposite to the second curvature. In some embodiments, the first section 146-1 has a concave surface and the second section 146-2 has a convex surface. In any case, the presence of the supporting layer 111′ prevents the epitaxial S/D feature 146 from growing into a region around the lower portion of the supporting layer 111′. The gap 113 remains open after formation of the epitaxial S/D features 146 and becomes an air gap (or air corner) 115 going around the lower portion of the supporting layer 111′. The air gap 115 is confined by a bottom surface of the epitaxial S/D feature 146, a sidewall of the dielectric spacer 144, a sidewall of the supporting layer 111′, and the top surface of the substrate 101. Particularly, the air gap 115 can effectively reduce capacitance between the epitaxial source/drain feature 146 and the subsequent gate electrode layer (e.g., gate electrode layer 182, FIG. 26A) in the replacement gate structure.

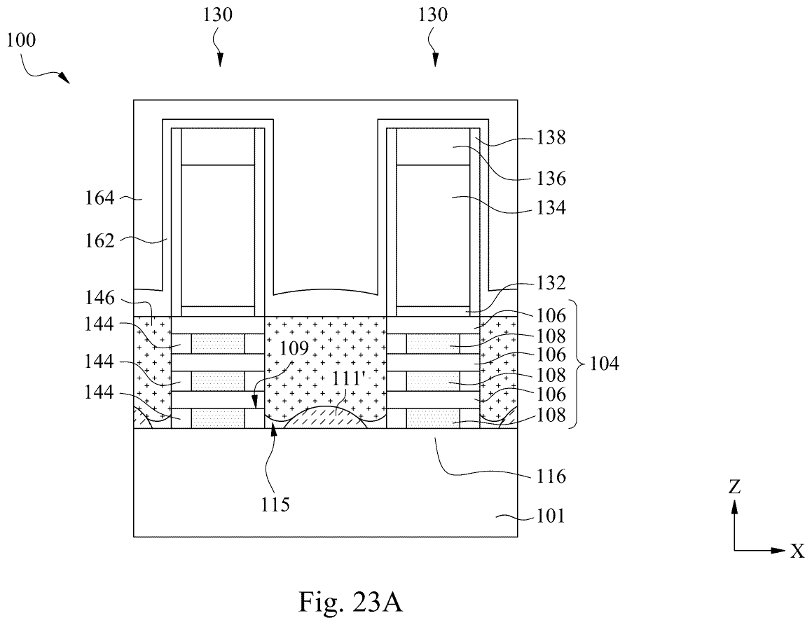

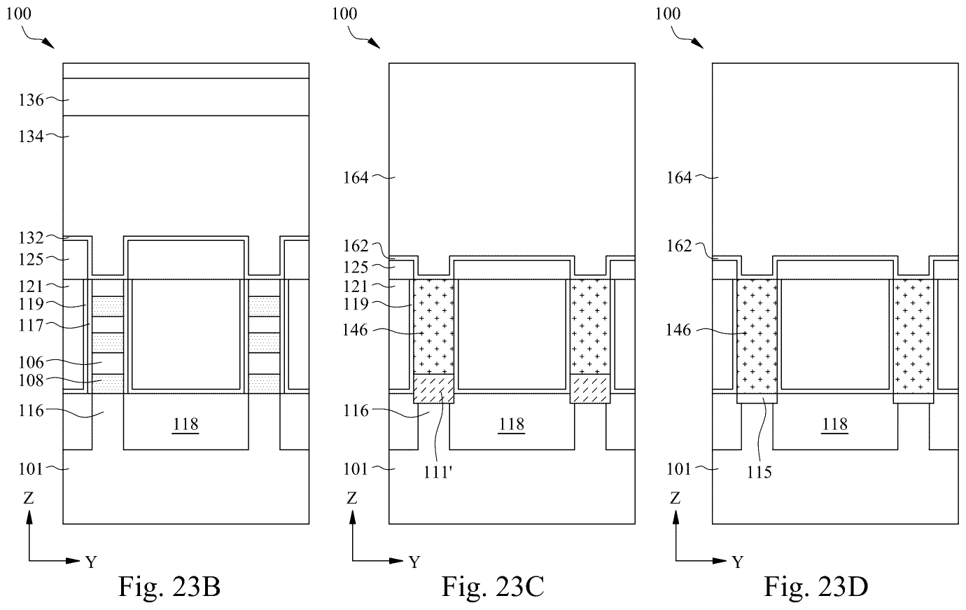

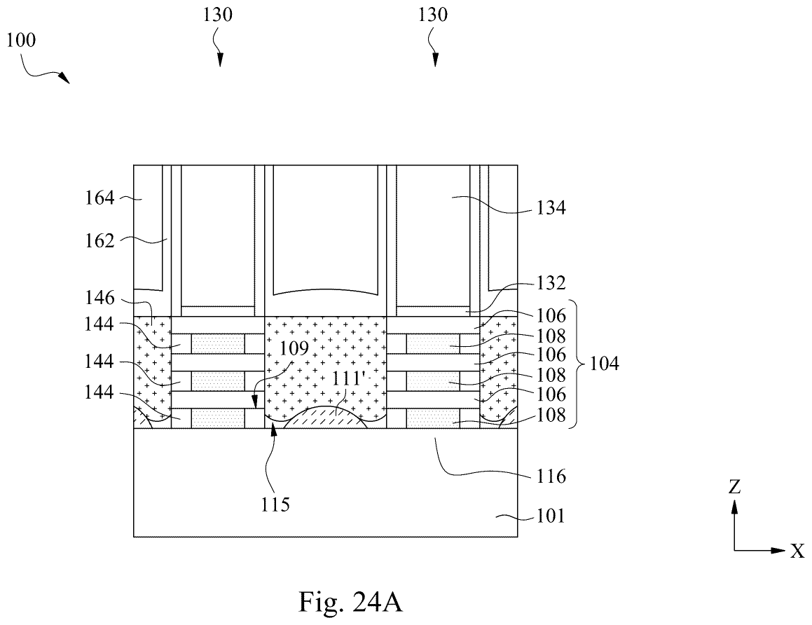

At block 1040, a contact etch stop layer (CESL) 162 is conformally formed on the exposed surfaces of the semiconductor device structure 100, as shown in FIGS. 23A-23D. The CESL 162 covers the top surfaces of the sacrificial gate structure 130, the insulating material 118, the epitaxial S/D features 146, and the exposed surface of the stack of semiconductor layers 104. The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. Next, an interlayer dielectric (ILD) layer 164 is formed on the CESL 162 over the semiconductor device structure 100. The materials for the ILD layer 164 may include compounds comprising Si, O, C, and/or H, such as silicon oxide, TEOS oxide, SiCOH and SiOC. Organic materials, such as polymers, may also be used for the ILD layer 164. The ILD layer 164 may be deposited by a PECVD process or other suitable deposition technique.

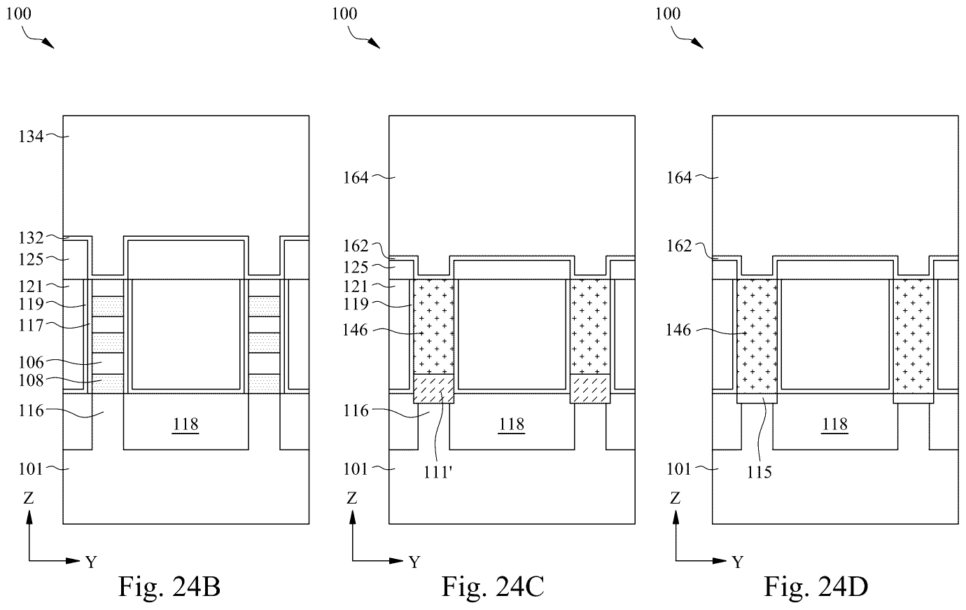

At block 1042, after the ILD layer 164 is formed, a planarization operation, such as CMP, is performed on the semiconductor device structure 100 until the sacrificial gate electrode layer 134 is exposed, as shown in FIGS. 24A-24D.

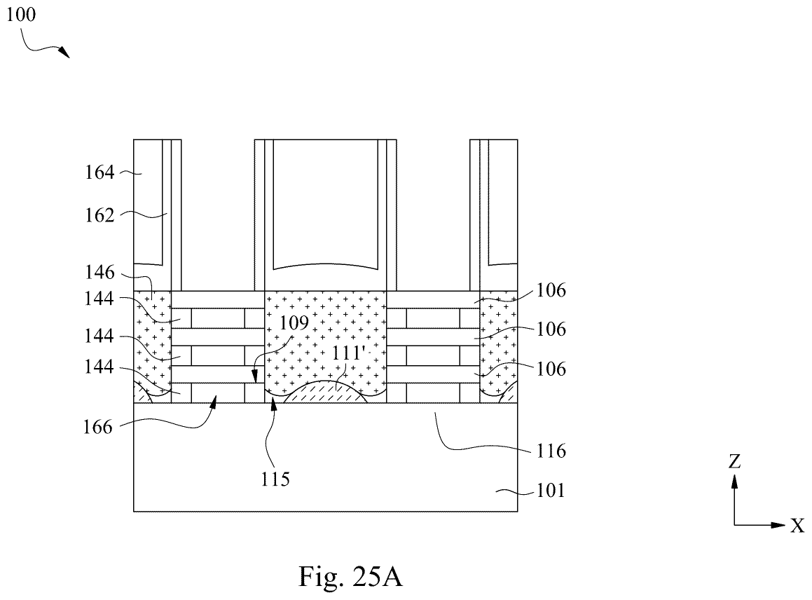

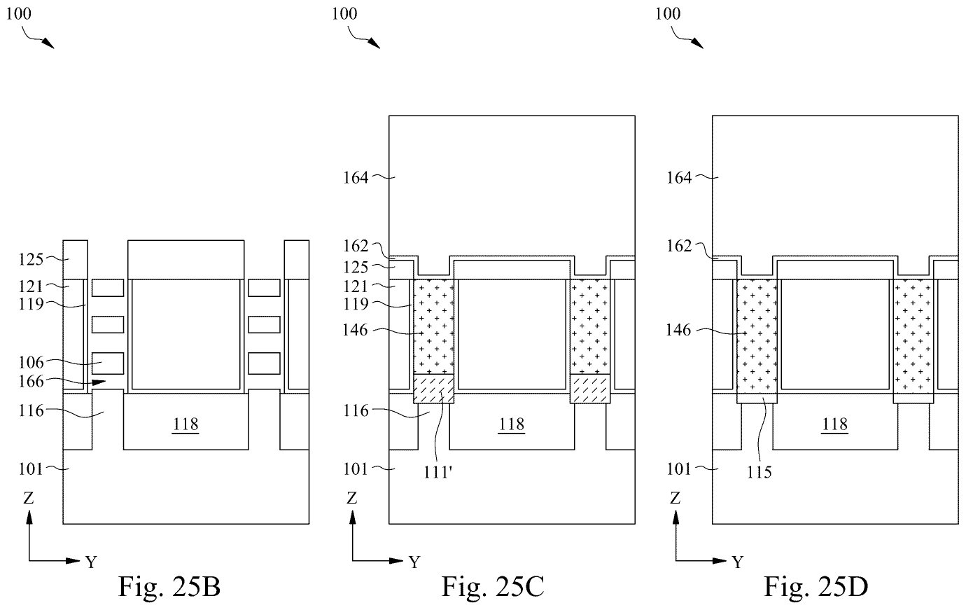

At block 1044, the sacrificial gate structure 130 and the second semiconductor layers 108 are sequentially removed, as shown in FIGS. 25A-25D. The removal of the sacrificial gate structure 130 and the semiconductor layers 108 forms an opening 166 between gate spacers 138 and between adjacent first semiconductor layers 106. The ILD layer 164 protects the epitaxial S/D features 146 during the removal processes. The sacrificial gate structure 130 can be removed using plasma dry etching and/or wet etching. The sacrificial gate electrode layer 134 may be first removed by any suitable process, such as dry etch, wet etch, or a combination thereof, followed by the removal of the sacrificial gate dielectric layer 132, which may also be performed by any suitable process, such as dry etch, wet etch, or a combination thereof.

The removal of the sacrificial gate structure 130 exposes the first semiconductor layers 106 and the second semiconductor layers 108. An etch process, which may be any suitable etch processes, such as dry etch, wet etch, or a combination thereof, is then performed to remove the second semiconductor layers 108 and expose the dielectric spacers 144. The etch process may be a selective etch process that removes the second semiconductor layers 108 but not the gate spacers 138, the dielectric spacers 144, the ILD layer 164, the CESL 162, and the first semiconductor layers 106. In one embodiment, the second semiconductor layers 108 can be removed using a wet etchant such as, but not limited to, hydrofluoric (HF), nitric acid (HNO₃), hydrochloric acid (HCl), phosphoric acid (H₃PO₄), a dry etchant such as fluorine-based (e.g., F₂) or chlorine-based gas (e.g., Cl₂), or any suitable isotropic etchants. After the etch process, a portion of the first semiconductor layers 106 not covered by the dielectric spacers 144 is exposed through the opening 166.

At block 1046, replacement gate structures 190 are formed, as shown in FIGS. 26A-26D. Each replacement gate structure 190 may include an interfacial layer (IL) 178, a gate dielectric layer 180, and a gate electrode layer 182. The interfacial layer (IL) 178 is formed to surround exposed surfaces of the first semiconductor layers 106 along the channel regions. The IL 178 may include or be made of an oxide (e.g., silicon oxide) formed by thermal or chemical oxidation of the first semiconductor layers 106, a nitride (e.g., silicon nitride, silicon oxynitride, oxynitride, etc.), and/or a dielectric layer (e.g., hafnium silicate). The IL 178 may be formed by CVD, ALD, a clean process, or any suitable process. Next, the gate dielectric layer 180 is formed on the exposed surfaces of the semiconductor device structure 100 (e.g., on the IL 178, sidewalls of the gate spacers 138, the top surfaces of the first ILD layer 164, the CESL 162, and the dielectric spacers 144). The gate dielectric layer 180 may include or made of a high-k dielectric material, such as hafnium oxide (HfO₂), hafnium silicate (HfSiO), hafnium silicon oxynitride (HfSiON), hafnium aluminum oxide (HfAlO), hafnium lanthanum oxide (HfLaO), hafnium zirconium oxide (HfZrO), hafnium tantalum oxide (HfTaO), hafnium titanium oxide (HfTiO), lanthanum oxide (LaO), aluminum oxide (AlO), aluminum silicon oxide (AlSiO), zirconium oxide (ZrO), titanium oxide (TiO), tantalum oxide (Ta₂O₅), yttrium oxide (Y₂O₃), silicon oxynitride (SiON), or other suitable high-k materials. The gate dielectric layer 180 may be a conformal layer formed by a conformal process, such as an ALD process, a PECVD process, a molecular-beam deposition (MBD) process, or the like, or a combination thereof.

After formation of the IL 178 and the gate dielectric layer 180, the gate electrode layer 182 is formed on the gate dielectric layer 180. The gate electrode layer 182 filles the openings 166 (FIGS. 25A and 25B) and surrounds a portion of each of the first semiconductor layers 106. The gate electrode layer 182 includes one or more layers of conductive material, such as polysilicon, aluminum, copper, titanium, tantalum, tungsten, cobalt, molybdenum, tantalum nitride, nickel silicide, cobalt silicide, TIN, WN, WCN, TiAl, TiTaN, TiAlN, TaN, TaCN, TaC, TaSiN, metal alloys, other suitable materials, and/or combinations thereof. The gate electrode layers 182 may be formed by PVD, CVD, ALD, electro-plating, or other suitable method. In some embodiments, one or more optional conformal layers (not shown) can be conformally (and sequentially, if more than one) deposited between the gate dielectric layer 180 and the gate electrode layer 182. The one or more optional conformal layers can include one or more barrier and/or capping layers and one or more work-function tuning layers. The one or more barrier and/or capping layers may include or be a nitride, silicon nitride, carbon nitride, and/or aluminum nitride of tantalum and/or titanium; a nitride, carbon nitride, and/or carbide of tungsten; the like; or a combination thereof. The one or more work-function tuning layers may include or be a nitride, silicon nitride, carbon nitride, aluminum nitride, aluminum oxide, and/or aluminum carbide of titanium and/or tantalum; a nitride, carbon nitride, and/or carbide of tungsten; cobalt; platinum; the like; or a combination thereof.

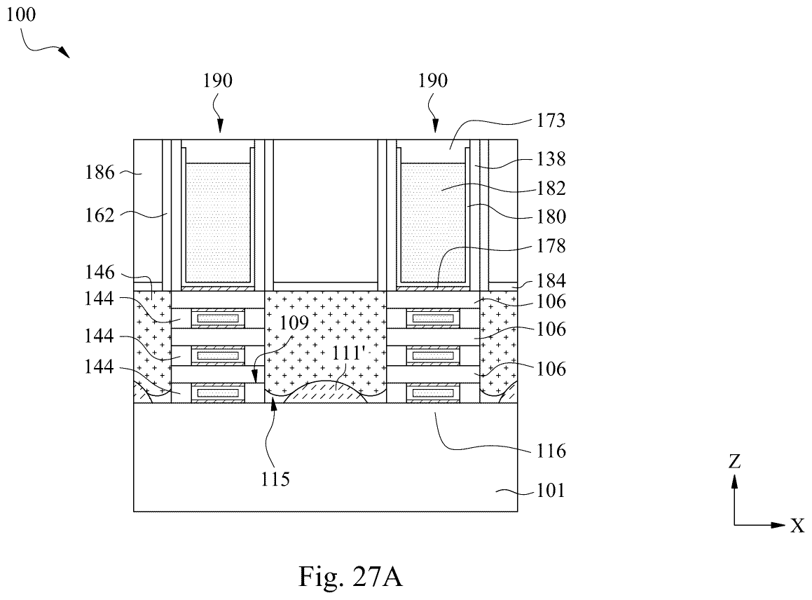

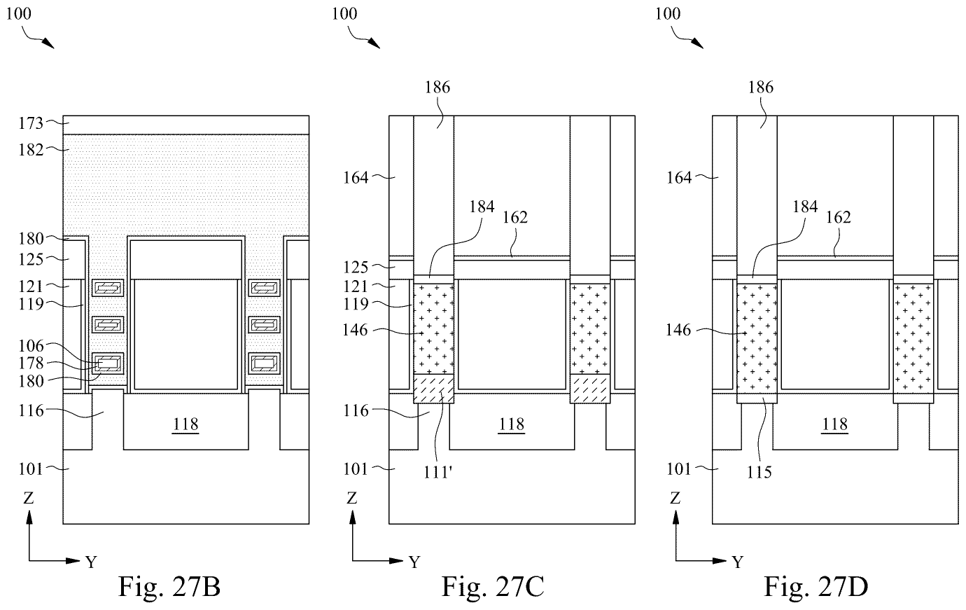

At block 1048, the gate electrode layer 182 may be subject to one or more metal gate etching back (MGEB) processes. The MGEB processes are performed so that the top surfaces of the gate electrode layer 182 and the gate dielectric layer 180 are recessed to a level below the top surface of the gate spacers 138. In some embodiments, the gate spacers 138 are also recessed to a level below the top surface of the ILD layer 164. A self-aligned contact layer 173 is formed over the gate electrode layer 182 and the gate dielectric layer 180 between the gate spacers 138, as shown in FIGS. 27A-27B. The self-aligned contact layer 173 may be a dielectric material having an etch selectivity relative to the ILD layer 164. In some embodiments, the self-aligned contact layer 173 includes silicon nitride.

Then, contact openings are formed through the ILD layer 164, and the CESL 162 to expose the epitaxial S/D feature 146. A silicide layer 184 is then formed on the S/D epitaxial features 146, and a source/drain (S/D) contact 186 is formed in the contact opening on the silicide layer 184. The S/D contact 186 may include an electrically conductive material, such as Ru, Mo, Co, Ni, W, Ti, Ta, Cu, Al, TiN, or TaN. The silicide layer 184 may include a metal or metal alloy silicide, and the metal includes a noble metal, a refractory metal, a rare earth metal, alloys thereof, or combinations thereof. Next, a conductive material is formed in the contact openings and form the S/D contacts 186, as shown in FIGS. 27A and 27B. The conductive material may be made of a material including one or more of Ru, Mo, Co, Ni, W, Ti, Ta, Cu, Al, TiN and TaN. While not shown, a barrier layer (e.g., TiN, TaN, or the like) may be formed on sidewalls of the contact openings prior to forming the S/D contacts 186. Then, a planarization process, such as CMP, is performed to remove excess deposition of the contact material and expose the top surface of the gate electrode layer 182.

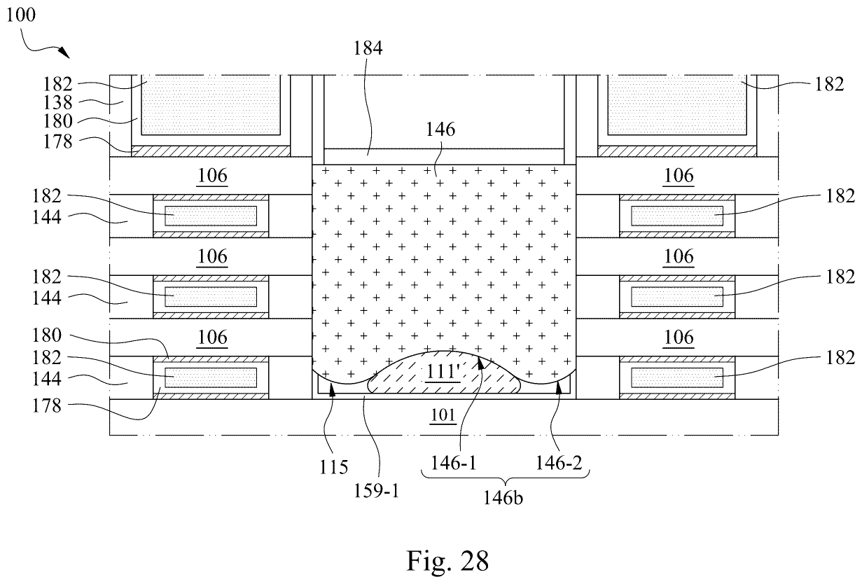

FIG. 28 illustrates an enlarged view of a portion of the semiconductor device structure 100, in accordance with some embodiments. The embodiment shown in FIG. 28 is substantially similar to the embodiment of FIG. 22A-1 except that a liner 159-1, such as the liner 159 discussed above with respect to FIGS. 21-1A to 21-2, is disposed between the supporting layer 111′ and the substrate 101. In this embodiment, the liner 159-1 covers the entire top surface of the substrate 101 and is extended upwardly to cover the sidewall surface of the bottommost dielectric spacers 144. As can be seen, the top surface of the supporting layer 111′ has a rounded head or curved (e.g., convex) profile in contact with the first section 146-1 of the bottom surface 146b of the epitaxial S/D feature 146. Particularly, the top surface of the supporting layer 111′ is disposed at an elevation higher than a bottom surface of the bottommost first semiconductor layer 106. The supporting layer 111′ has a substantially flat bottom surface in contact with the liner 159-1. The air gap 115 is confined by the second section 146-2 of the bottom surface 146b of the epitaxial S/D feature 146, the sidewall of the supporting layer 111′, and the liner 159-1.

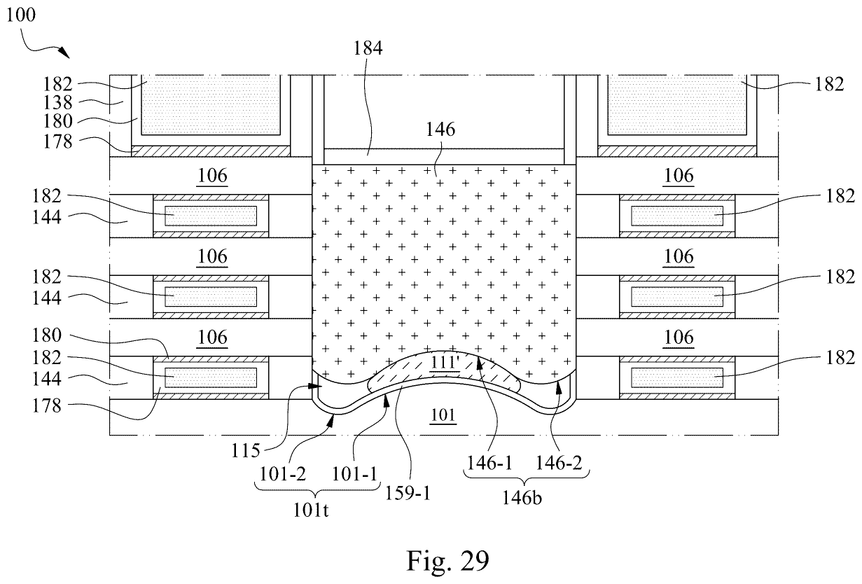

FIG. 29 illustrates an enlarged view of a portion of the semiconductor device structure 100, in accordance with some embodiments. The embodiment shown in FIG. 29 is substantially similar to the embodiment of FIG. 28 except that the supporting layer 111′ has a curved bottom surface that follows the curved profile of the top surface of the substrate 101. In this embodiment, the substrate 101 between neighboring replacement gate structures 190 has a curved (e.g., convex) top surface. After formation of the recess 139 (FIG. 9A), the top surface of the substrate 101 may be etched to form a concave top surface. In some cases, a deposition process is performed to redeposit the material (e.g., silicon) on the concave top surface so that the top surface of the substrate 101 becomes a convex profile as shown. The liner 159-1 and the supporting layer 111′ thus follow the convex profile of the substrate 101. Likewise, the air gap 115 is confined by the second section 146-2 of the bottom surface 146b of the epitaxial S/D feature 146, the sidewall of the supporting layer 111′, and the liner 159-1.

In some embodiments, the top surface 101t of the substrate 101 has a first section 101-1 and a second section 101-2 surrounding the first section 101-1. The first section 101-1 is a curved surface having a first curvature and the second section 101-2 is a curved surface having a second curvature. In some embodiments, the first curvature is different than the second curvature. In some embodiments, the first curvature is opposite to the second curvature. In some embodiments, the first section 101-1 has a convex surface and the second section 101-2 has a concave surface.

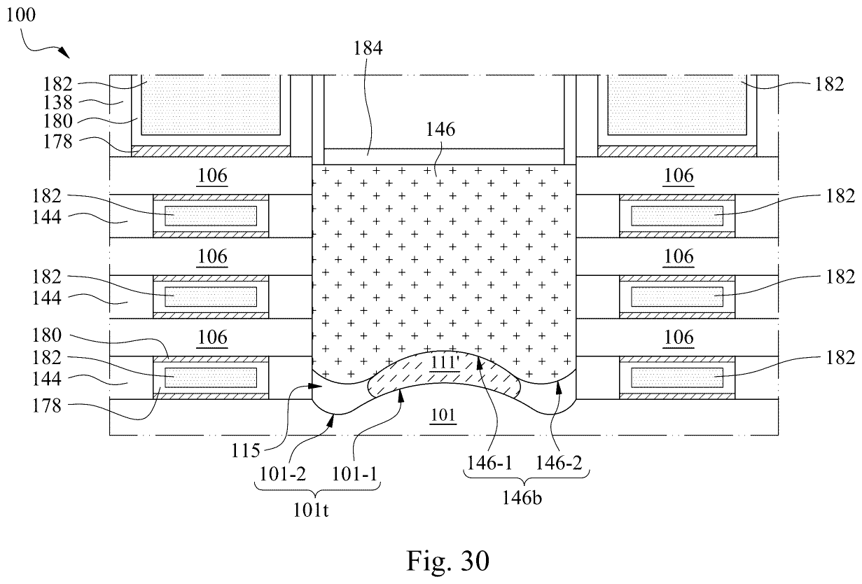

FIG. 30 illustrates an enlarged view of a portion of the semiconductor device structure 100, in accordance with some embodiments. The embodiment shown in FIG. 30 is similar to the embodiment of FIG. 29 except that the supporting layer 111′ is formed directly on a curved top surface of the substrate 101 without the liner 159-1 disposed between the supporting layer 111′ and the substrate 101.

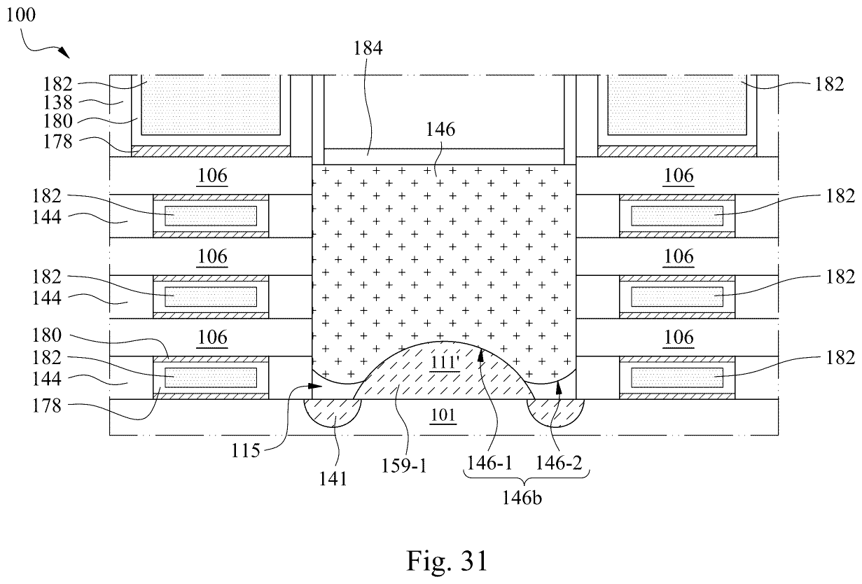

FIG. 31 illustrates an enlarged view of a portion of the semiconductor device structure 100, in accordance with some embodiments. The embodiment shown in FIG. 31 is similar to the embodiment of FIG. 22A-1 except that the surface portion of the substrate 101 is further nitridized or oxidized to form a nitridized or oxidized region 141, as the process discussed above with respect to FIGS. 14 and 14-1. In some embodiments, the nitridized or oxidized region 141 extends radially in the substrate 101 and in contact with a bottom surface of the bottommost dielectric spacer 144 and a portion of the bottom surface of the supporting layer 111′. The air gap 115 is confined by the second section 146-2 of the bottom surface 146b of the epitaxial S/D feature 146, the sidewall of the supporting layer 111′, the sidewall of the dielectric spacer 144, and the nitridized or oxidized region 141.

Various embodiments of the present disclosure relate to a nanosheet device structure having a supporting layer disposed between a substrate and an epitaxial source/drain feature. The supporting layer is formed by a bottom-up deposition technique and has a rounded head with a convex profile to help induce an air gap formation during the epitaxial source/drain features. The air gap goes around a lower portion of the supporting layer at a corner between the substrate and a bottommost dielectric spacer of the nanosheet device structure. The air gap can effectively reduce capacitance between the epitaxial source/drain features and the gate. As a result, the device performance is improved.

An embodiment is a semiconductor device structure. The semiconductor device structure includes a source/drain (S/D) feature disposed over a substrate between two adjacent semiconductor layers, a supporting layer disposed between the S/D feature and the substrate, the supporting layer having a curved top surface, a dielectric spacer disposed between and in contact with one of the semiconductor layers and the substrate, wherein the dielectric spacer, the substrate, the supporting layer, and a bottom surface of the S/D feature define an air gap therein.

Another embodiment is a method for forming a semiconductor device structure. The method includes forming a first fin structure and a second fin structure from a substrate, each fin structure comprising a plurality of first semiconductor layers and a plurality of second semiconductor layers alternately stacked, depositing a sacrificial gate structure over a portion of the first and second fin structures, removing portions of the first and second fin structures not covered by the sacrificial gate structure to form a recess on opposite sides of the sacrificial gate structure, forming a base layer on a portion of a top surface of the substrate exposed through the recess, the base layer having a curved top surface, trimming the base layer to reduce its thickness, treating the trimmed base layer with plasma or radical species to convert the base layer into a supporting layer, forming a source/drain (S/D) feature on the supporting layer, wherein the S/D feature covers a top portion of the supporting layer, forming an air gap between a bottom surface of the S/D feature and the top surface of the substrate, removing the plurality of second semiconductor layers to expose portions of the first semiconductor layers, and forming a gate electrode layer surrounding at least the exposed portion of one of the plurality of first semiconductor layers.

A further embodiment is a method for forming a semiconductor device structure. The method includes providing a substrate with a first fin structure and a second fin structure, each comprising a stack of alternating first and second semiconductor layers, forming a sacrificial gate structure over a portion of the first and second fin structures, etching portions of the first and second fin structures not covered by the sacrificial gate structure to form a recess, depositing a base layer on a top surface of the substrate within the recess using a bottom-up epitaxial growth process, the base layer being separated from sidewalls of the first semiconductor layers by a gap, converting the base layer into a supporting layer by a plasma treatment process, forming a source/drain (S/D) feature over the supporting layer, wherein an air gap is maintained between the S/D feature, the supporting layer, a dielectric spacer, and the substrate, removing the sacrificial gate structure and the second semiconductor layers to expose portions of the first semiconductor layers, and forming a replacement gate structure surrounding the exposed portions of the first semiconductor layers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
a source/drain (S/D) feature disposed over a substrate between two adjacent semiconductor layers;
a supporting layer disposed between the S/D feature and the substrate, the supporting layer having a curved top surface; and
a dielectric spacer disposed between and in contact with one of the semiconductor layers and the substrate,
wherein the dielectric spacer, the substrate, the supporting layer, and a bottom surface of the S/D feature define an air gap therein.

2. The semiconductor device structure of claim 1, wherein the supporting layer comprises a material selected from the group consisting of silicon nitride and silicon oxide.

3. The semiconductor device structure of claim 1, wherein the bottom surface of the S/D feature comprises a first section with a concave curvature and a second section with a convex curvature surrounding the first section.

4. The semiconductor device structure of claim 1, further comprising:
a liner disposed between the supporting layer and the substrate, the liner covering an entire top surface of the substrate.

5. The semiconductor device structure of claim 4, wherein the liner extends to cover a sidewall of the dielectric spacer.

6. The semiconductor device structure of claim 4, wherein the liner comprises a material selected from the group consisting of silicon oxide and doped silicon.

7. The semiconductor device structure of claim 4, wherein the supporting layer and the liner comprise chemically different materials.

8. The semiconductor device structure of claim 1, wherein the substrate comprises a nitridized or oxidized region in contact with a bottom surface of the supporting layer and a sidewall of the dielectric spacer.

9. The semiconductor device structure of claim 1, wherein a highest point of the curved top surface of the supporting layer is at an elevation higher than a bottom surface of a bottommost semiconductor layer.

10. The semiconductor device structure of claim 1, wherein the supporting layer has a thickness in a range of about 4 nm to about 6 nm.

11. A method for forming a semiconductor device structure, comprising:
forming a first fin structure and a second fin structure from a substrate, each fin structure comprising a plurality of first semiconductor layers and a plurality of second semiconductor layers alternately stacked;
depositing a sacrificial gate structure over a portion of the first and second fin structures;
removing portions of the first and second fin structures not covered by the sacrificial gate structure to form a recess on opposite sides of the sacrificial gate structure;
forming a base layer on a portion of a top surface of the substrate exposed through the recess, the base layer having a curved top surface;
trimming the base layer to reduce its thickness;
treating the trimmed base layer with plasma or radical species to convert the base layer into a supporting layer;
forming a source/drain (S/D) feature on the supporting layer, wherein the S/D feature covers a top portion of the supporting layer, forming an air gap between a bottom surface of the S/D feature and the top surface of the substrate;
removing the plurality of second semiconductor layers to expose portions of the first semiconductor layers; and
forming a gate electrode layer surrounding at least the exposed portion of one of the plurality of first semiconductor layers.

12. The method of claim 11, wherein forming the base layer comprises depositing silicon using a plasma-assisted chemical vapor deposition (CVD) process with a bottom-up growth technique.

13. The method of claim 11, wherein trimming the base layer comprises performing a wet etch process using a solution selected from the group consisting of ammonium hydroxide, hydrofluoric acid, and tetramethylammonium hydroxide.

14. The method of claim 11, wherein treating the base layer comprises a nitridation process using nitrogen-containing gas to convert the base layer into a silicon nitride supporting layer.

15. The method of claim 11, further comprising:
forming a liner on the top surface of the substrate and sidewalls of the first semiconductor layers before forming the base layer.

16. The method of claim 15, wherein the liner comprises boron-doped silicon and is formed using a selective deposition process.

17. A method for forming a semiconductor device structure, comprising:
providing a substrate with a first fin structure and a second fin structure, each comprising a stack of alternating first and second semiconductor layers;
forming a sacrificial gate structure over a portion of the first and second fin structures;
etching portions of the first and second fin structures not covered by the sacrificial gate structure to form a recess;
depositing a base layer on a top surface of the substrate within the recess using a bottom-up epitaxial growth process, the base layer being separated from sidewalls of the first semiconductor layers by a gap;
converting the base layer into a supporting layer by a plasma treatment process;
forming a source/drain (S/D) feature over the supporting layer, wherein an air gap is maintained between the S/D feature, the supporting layer, a dielectric spacer, and the substrate;
removing the sacrificial gate structure and the second semiconductor layers to expose portions of the first semiconductor layers; and
forming a replacement gate structure surrounding the exposed portions of the first semiconductor layers.

18. The method of claim 17, wherein the plasma treatment process comprises exposing the base layer to nitrogen radicals generated from a nitrogen-containing gas at a pressure of about 0.5 Torr to about 8 Torr.

19. The method of claim 17, further comprising:
forming a nitridized or oxidized region in the substrate adjacent to the supporting layer by the plasma treatment process.

20. The method of claim 17, wherein the supporting layer has a curved top surface with a highest point at an elevation between a top surface and a bottom surface of a bottommost first semiconductor layer.
